(19) United States
(12) Patent Application Publication
(10) Pub. No.: US 2023/0329036 A1
(43) Pub. Date: Oct. 12, 2023

(54) IMAGE DISPLAY DEVICE AND ELECTRONIC DEVICE

(71) Applicant: Sony Semiconductor Solutions Corporation, Kanagawa (JP)

(72) Inventor: Seiichiro Jinta, Kanagawa (JP)

(21) Appl. No.: 18/042,388

(22) PCT Filed: Aug. 24, 2021
(86) PCT No.: PCT/JP2021/031006

§ 371 Date: Feb. 21, 2023

(30) Foreign Application Priority Data
Sep. 3, 2020 (JP) 2020-148536

(51) Int. Cl. H10K 59/121; H10K 59/65

(52) U.S. Cl. CPC H10K 59/121; H10K 59/65

(57) ABSTRACT

[Problem] Provided is an image display device and an electronic device that can suppress the occurrence of diffracted light.

[Solution] An image display device includes a plurality of pixels arranged in a two-dimensional array, wherein the plurality of pixels include at least some pixels, each having: a first self-emitting device, a first luminous region illuminated by the first self-emitting device, and a nonluminous region having a transmissive window that allows the passage of visible light.

### TECHNICAL FIELD

The present disclosure relates to an image display device and an electronic device.

### BACKGROUND ART

In recent electronic devices such as a smartphone, a cellular phone, and a PC (Personal Computer), various sensors such as a camera are installed on the bezel of a display panel. The number of installed sensors tends to increase. For example, a sensor for face recognition, an infrared sensor, and a moving-object sensor are installed in addition to a camera. In view of the design and the trend toward miniaturization, electronic devices designed with minimum outer dimensions without affecting screen sizes are demanded, and bezel widths tend to decrease. Against this backdrop, a technique is proposed to image subject light, which has passed through a display panel, with an image sensor module disposed immediately under the display panel. In order to dispose the image sensor module immediately under the display panel, the display panel needs to be transparent (see PTL 1).

### CITATION LIST

### Patent Literature

### [PTL 1]

JP 2011-175962 A

### SUMMARY

### Technical Problem

However, each pixel of the display panel has opaque members such as a pixel circuit and a wiring pattern and further includes an insulating layer having a low transmittance. Thus, the image module disposed immediately under the display panel causes incident light on the display panel from being irregularly reflected, refracted, and diffracted in the display panel, so that the light generated by the reflection, refraction, and diffraction (hereinafter referred to as diffracted light) is caused to enter the image sensor module. Imaging with diffracted light may reduce the image quality of a subject image.

Hence, the present disclosure provides an image display device and an electronic device that can suppress the occurrence of diffracted light.

### Solution to Problem

In order to solve the above problem, the present disclosure provides an image display device including a plurality of pixels that are two-dimensionally arranged,
wherein the plurality of pixels include at least some pixels, each having: a first self-emitting device;
a first luminous region illuminated by the first self-emitting device; and a nonluminous region having a transmissive window in a predetermined shape that allows the passage of visible light.

The plurality of pixels may include at least two pixels including the nonluminous regions with the transmissive windows in different shapes.

In plan view from the display surface side of the image display device, the nonluminous region may be disposed at a position overlapping a light receiver for receiving light passing through the image display device.

A pixel circuit connected to the first self-emitting device may be disposed in the first luminous region.

The nonluminous region may have the plurality of transmissive windows spaced in one of the pixels.

The transmissive window may be disposed over at least two of the pixels.

The transmissive window disposed over at least two of the pixels may vary in shape and type.

The image display device may include an optical member that is disposed on the light entry side of the transmissive window and refracts incident light so as to guide the light into the transmissive window.

The optical member may include:
a first optical system that refracts incident light in the direction of an optical axis; and
a second optical system that collimates the light refracted by the first optical system,
wherein the transmissive window may allow the passage of the light collimated by the second optical system.

The image display device may include a first optical member that is disposed on the light entry side of the transmissive window and refracts incident light so as to guide the light into the transmissive window; and
a second optical member that is disposed on the light emission side of the transmissive window and collimates light from the transmissive window so as to guide the light into the light receiver.

The image display device may include: first pixel regions including some of the plurality of pixels; and
second pixel regions including at least some of the plurality of pixels other than the pixels in the first pixel regions,
wherein the pixel in the first pixel region may include the first self-emitting device, the first luminous region, and the nonluminous region, and
the pixel in the second pixel region may include:
a second self-emitting device; and
a second luminous region that is illuminated by the second self-emitting device and has a larger area than the first luminous region.

The first pixel regions may be spaced at a plurality of points in a pixel display region.

In the first pixel regions, at least two of the plurality of pixels may be provided with the transmissive windows in different shapes such that diffracted light generated by light having passed through the transmissive windows has different shapes.

The first self-emitting device may include:
a lower electrode layer;
a display layer disposed on the lower electrode layer;
an upper electrode layer disposed on the display layer; and
a wiring layer that is disposed under the lower electrode layer and is electrically connected to the lower electrode layer via a contact extending from the lower electrode layer in a stacking direction, and
the shape of the transmissive window in plan view from the display surface side of the plurality of pixels may be determined by the ends of the lower electrode layer.

The first self-emitting device may include:
a lower electrode layer;
a display layer disposed on the lower electrode layer;
an upper electrode layer disposed on the display layer; and
a wiring layer that is disposed under the lower electrode layer and is electrically connected to the lower electrode layer via a contact extending from the lower electrode layer in a stacking direction, and
the shape of the transmissive window in plan view from the display surface side of the plurality of pixels may be determined by the ends of the wiring layer.

The wiring layer may include a plurality of stacked metallic layers, and the shape of the transmissive window in plan view from the display surface side of the plurality of pixels may be determined by the ends of at least one of the plurality of metallic layers.

The metallic layer may be an electrode of a capacitor in the pixel circuit, the metallic layer determining the shape of the transmissive window in plan view from the display surface side of the plurality of pixels.

The first luminous region may be covered with the lower electrode layer except for the region of the transmissive window.

Another aspect of the present disclosure provides an electronic device including: an image display device including a plurality of pixels that are two-dimensionally arranged, and
a light receiver that receives light passing through the image display device, wherein the image display device has first pixel regions including some of the plurality of pixels,
the pixels in the first pixel regions each include:
a first self-emitting device;
a first luminous region illuminated by the first self-emitting device; and
a nonluminous region having a transmissive window in a predetermined shape that allows the passage of visible light, and
in plan view from the display surface side of the image display device, at least some of the first pixel regions are disposed so as to overlap the light receiver.

The light receiver may receive light through the nonluminous region.

The light receiver may include at least one of an imaging sensor that performs photoelectric conversion on incident light passing through the nonluminous region, a distance measuring sensor that receives incident light passing through the nonluminous region and measures a distance, and a temperature sensor that measures a temperature on the basis of incident light passing through the nonluminous region.

### BRIEF DESCRIPTION OF DRAWINGS

FIG. 1 shows a broken line indicating an example of a specific location of a sensor disposed immediately under a display panel.

FIG. 2A illustrates an example in which the two sensors are disposed on the backside of the display panel and are located on the upper side with respect to the center of the display panel.

FIG. 2B illustrates an example in which the sensors 5 are disposed at the four corners of the display panel.

FIG. 3 is a schematic diagram illustrating the structure of a pixel in a first pixel region and the structure of a pixel in a second pixel region.

FIG. 4 is a cross-sectional view illustrating an image sensor module.

FIG. 5 is an explanatory drawing schematically illustrating the optical configuration of the image sensor module.

FIG. 6 is an explanatory drawing illustrating an optical path where light from a subject forms an image on an image sensor.

FIG. 7 is a circuit diagram of the basic configuration of a pixel circuit including an OLED.

FIG. 8 is a plan layout view of the pixels in the second pixel regions.

FIG. 9 is a cross-sectional view of the pixel in the second pixel region that is not disposed directly above the sensor.

FIG. 10 is a cross-sectional view illustrating an example of the laminated structure of a display layer.

FIG. 11 is a plan layout view of the pixels in the first pixel regions that are disposed directly above the sensor.

FIG. 12 is a cross-sectional view of the pixel in the first pixel region that is disposed directly above the sensor.

FIG. 13 is an explanatory drawing of a diffraction phenomenon that generates diffracted light.

FIG. 14 is a plan layout view of an image display device according to an embodiment.

FIG. 15 is a plan layout view of an anode electrode disposed over a second luminous region in the pixel.

FIG. 16 is a cross-sectional view illustrating a first example of the cross-sectional structure of the first pixel region.

FIG. 17 is a cross-sectional view illustrating a second example of the cross-sectional structure of the first pixel region.

FIG. 18 is a cross-sectional view illustrating a third example of the cross-sectional structure of the first pixel region.

FIG. 19 is a plan layout view according to a first modification of FIG. 14.

FIG. 20 is a cross-sectional view taken along line A-A of FIG. 19.

FIG. 21 is a plan layout view according to a second modification of FIG. 14.

FIG. 22 is a cross-sectional view taken along line A-A of FIG. 21.

FIG. 23 is a plan layout view according to a third modification of FIG. 14.

FIG. 24 is a cross-sectional view taken along line A-A of FIG. 23.

FIG. 25 is a circuit diagram showing a first example of the detailed circuit configuration of the pixel circuit.

FIG. 26 is a circuit diagram showing a second example of the detailed circuit configuration of the pixel circuit.

FIG. 27 is a plan layout view according to a fourth modification of FIG. 14.

FIG. 28 is a cross-sectional view taken along line A-A of FIG. 27.

FIG. 29A illustrates an example of rectangular transmissive windows.

FIG. 29B illustrates diffracted light generated when parallel rays are projected into the transmissive window of FIG. 29A.

FIG. 30A illustrates an example of circular transmissive windows.

FIG. 30B illustrates diffracted light generated when parallel rays are projected into the transmissive window of FIG. 30A.

FIG. 31A illustrates an example in which a plurality of transmissive windows are provided in a nonluminous region.

FIG. 31B illustrates diffracted light generated when parallel rays are projected into the transmissive windows of FIG. 31A.

FIG. 32 illustrates a first example of the removal of diffracted light.

FIG. 33 illustrates a second example of the removal of diffracted light.

FIG. 34 illustrates an example of the single transmissive window provided over the three pixels.

FIG. 35 illustrates a third example of the removal of diffracted light.

FIG. 36 is a cross-sectional view illustrating an example in which a microlens is disposed on the light entry side of the first pixel region.

FIG. 37A illustrates arrows indicating the traveling direction of light entering the first pixel region in the absence of the microlens.

FIG. 37B illustrates arrows indicating the traveling direction of light in the presence of the microlens of FIG. 36.

FIG. 38 illustrates arrows indicating the traveling direction of light refracted through the microlens.

FIG. 39 is a cross-sectional view illustrating a plurality of microlenses disposed to protrude in different directions on the light entry side of the first pixel region.

FIG. 40 is a cross-sectional view illustrating the microlens disposed on the light entry side of the first pixel region and another microlens disposed on the light emission side of the first pixel region.

FIG. 41 illustrates arrows indicating the traveling direction of light passing through the two microlenses of FIG. 40.

FIG. 42 is a plan view of an electronic device applied to a capsule endoscope according to a first embodiment.

FIG. 43 is a rear view of the electronic device applied to a digital single-lens reflex camera according to the first embodiment.

FIG. 44A is a plan view illustrating the electronic device applied to an HMD according to the first embodiment.

FIG. 44B illustrates an existing HMD.

### DESCRIPTION OF EMBODIMENTS

Embodiments of an image display device and an electronic device will be described below with reference to the drawings. Hereinafter, the main components of the image display device and the electronic device will be mainly described. The image display device and the electronic device may include components and functions that are not illustrated or explained. The following description does not exclude components or functions that are not illustrated or described.

### First Embodiment

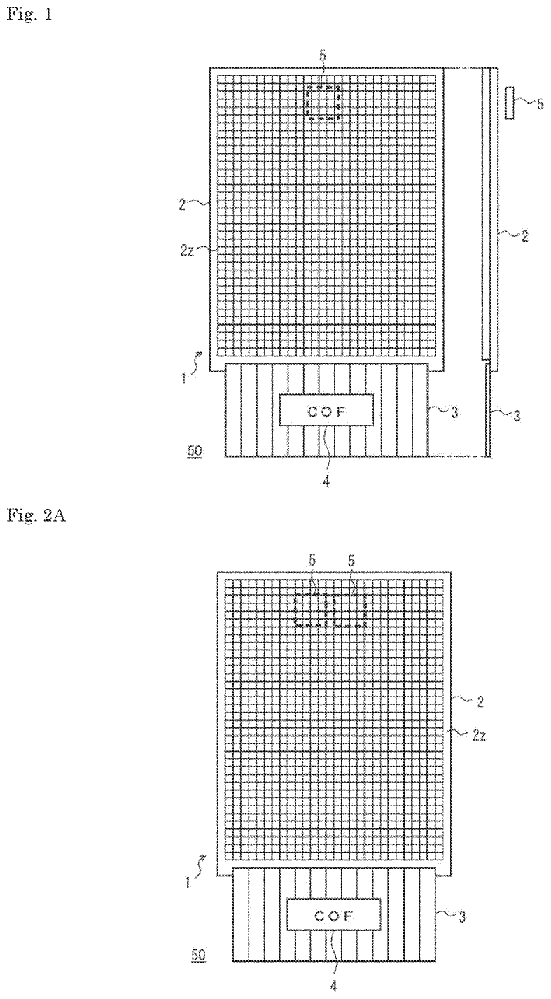

FIG. 1 illustrates a plan view and a cross-sectional view of an electronic device 50 including an image display device 1 according to a first embodiment of the present disclosure. As illustrated in FIG. 1, the image display device 1 according to the present embodiment includes a display panel 2. For example, flexible printed circuits (FPCs) 3 are connected to the display panel 2. The display panel 2 includes, for example, a plurality of layers stacked on a glass substrate or a transparent film and has a matrix of pixels disposed on a display surface 2z. On the FPCs 3, a chip (COF: Chip On Film) 4 containing at least a part of the drive circuit of the display panel 2 is mounted. The drive circuit may be stacked as COG (Chip On Glass) on the display panel 2.

The image display device 1 according to the present embodiment is configured such that various sensors 5 for receiving light through the display panel 2 can be disposed immediately under the display panel 2. In the present specification, a configuration including the image display device 1 and the sensors 5 will be referred to as the electronic device 50. The kinds of sensors 5 provided in the electronic device 50 are not particularly specified. For example, the sensor 5 may be an imaging sensor that performs photoelectric conversion on incident light passing through the display panel 2, a distance measuring sensor that projects light through the display panel 2, receives light, which is reflected by an object, through the display panel 2, and measures a distance to the object, or a temperature sensor that measures a temperature on the basis of incident light passing through the display panel 2. As described above, the sensor 5 disposed immediately under the display panel 2 has at least the function of a light receiver for receiving light. The sensor 5 may have the function of a light emitter for projecting light through the display panel 2.

FIG. 1 illustrates an example of a specific location of the sensor 5 disposed immediately under the display panel 2 by a broken line. As illustrated in FIG. 1, for example, the sensor 5 is disposed on the backside of the display panel 2 and is located on the upper side of the display panel 2 with respect to the center of the display panel 2. The location of the sensor 5 in FIG. 1 is merely exemplary. The sensor 5 may be disposed at any location. As illustrated in FIG. 1, the sensor 5 is disposed on the backside of the display panel 2. This can eliminate the need for disposing the sensor 5 on the side of the display panel 2, minimize the size of the bezel of the electronic device 50, and place the display panel 2 substantially over the front side of the electronic device 50.

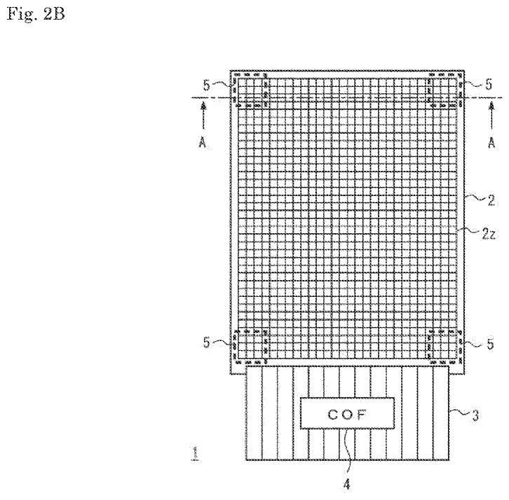

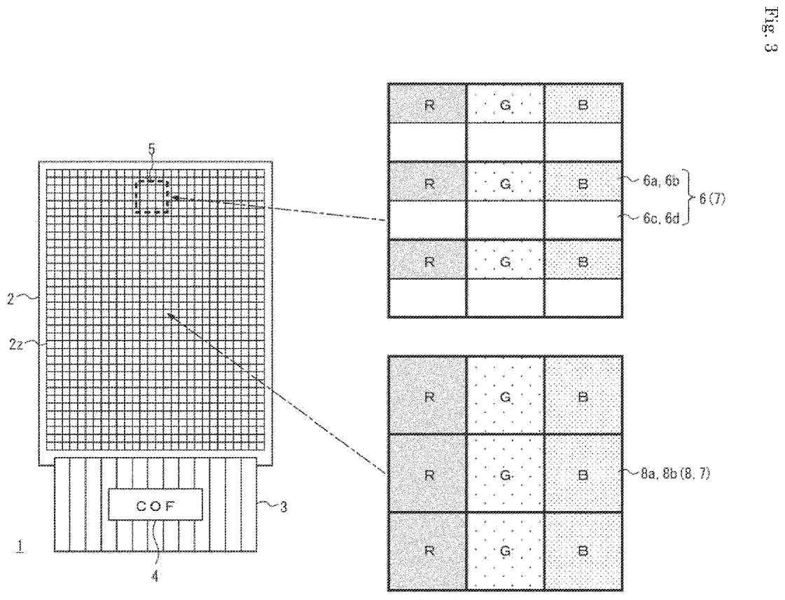

FIG. 1 illustrates an example in which the sensor 5 is disposed at one location of the display panel 2. As illustrated in FIG. 2A or 2B, the sensors 5 may be disposed at multiple locations. FIG. 2A illustrates an example in which the two sensors 5 are disposed on the backside of the display panel 2 and are located on the upper side with respect to the center of the display panel 2. FIG. 2B illustrates an example in which the sensors 5 are disposed at the four corners of the display panel 2. The sensors 5 are disposed at the four corners of the display panel 2 as illustrated in FIG. 2B for the following reason: A pixel region overlapping the sensors 5 in the display panel 2 is designed with an increased transmittance and thus may have display quality slightly different from that of a surrounding pixel region. A human staring at the center of the screen can closely recognize the center of screen in a central visual field and notice a small difference. However, detail visibility decreases in an outer region of the screen, that is, a peripheral visual field. Since the center of the screen is frequently viewed in a typical display image, the sensors 5 are recommended to be located at the four corners to make the difference less noticeable.

As illustrated in FIGS. 2A and 2B, in the case of the plurality of sensors 5 disposed on the backside of the display panel 2, the sensors 5 may be of the same type or different types. For example, a plurality of image sensor modules 9 having different focal lengths may be disposed, or the sensors 5 of different types, for example, an imaging sensor 5 and a ToF (Time of Flight) sensor 5 may be disposed.

In the present embodiment, a pixel region (first pixel region) overlapping the sensor 5 on the backside and a pixel region (second pixel region) not overlapping the sensor 5 have different pixel structures. FIG. 3 is a schematic diagram illustrating the structure of a pixel 7 in a first pixel region 6 and the structure of the pixel 7 in a second pixel region 8. The pixel 7 in the first pixel region 6 includes a first self-emitting device 6a, a first luminous region 6b, and a nonluminous region 6c. The first luminous region 6b is a region illuminated by the first self-emitting device 6a. The nonluminous region 6c is not illuminated by the first self-emitting device 6a but has a transmissive window 6d in a predetermined shape that allows the passage of visible light. The pixel 7 in the second pixel region 8 includes a second self-emitting device 8a and a second luminous region 8b. The second luminous region 8b is illuminated by the second self-emitting device 8a and has a larger area than the first luminous region 6b.

A representative example of the first self-emitting device 6a and the second self-emitting device 8a is an organic EL (Electroluminescence) device (hereinafter also referred to as an OLED: Organic Light Emitting Diode). At least a part of the self-emitting device can be made transparent because the backlight can be omitted. The use of an OLED as an example of the self-emitting device will be mainly described below.

Instead of the different structures of the pixels 7 in the pixel region overlapping the sensor 5 and the pixel region not overlapping the sensor 5, the same structure may be provided for all the pixels 7 in the display panel 2. In this case, each of the pixels 7 preferably includes the first luminous region 6b and the nonluminous region 6c of FIG. 3 such that the sensor 5 can be disposed at any location in the display panel 2.

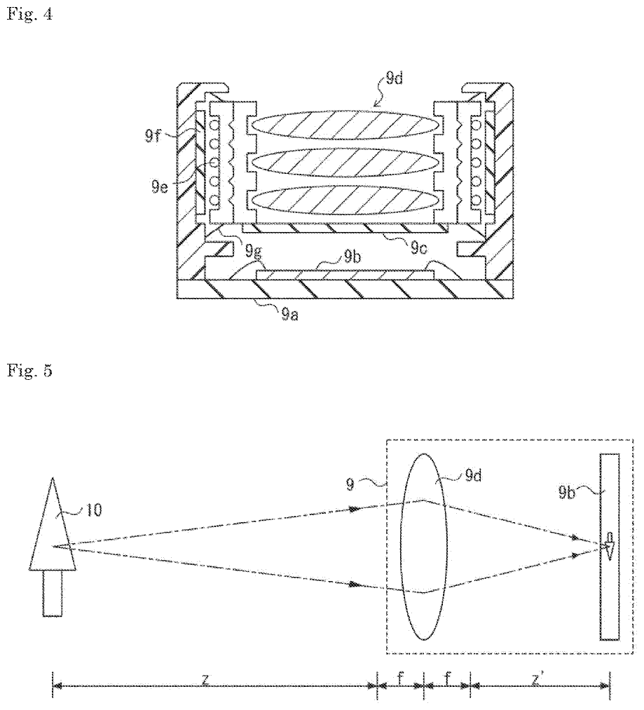

FIG. 4 is a cross-sectional view illustrating the image sensor module 9. As illustrated in FIG. 4, the image sensor module 9 includes an image sensor 9b mounted on a support substrate 9a, an IR (Infrared Ray) cutoff filter 9c, a lens unit 9d, a coil 9e, a magnet 9f, and a spring 9g. The lens unit 9d includes one or more lenses. The lens unit 9d can move along the optical axis according to the direction of current passing through the coil 9e. The internal configuration of the image sensor module 9 is not limited to that illustrated in FIG. 4.

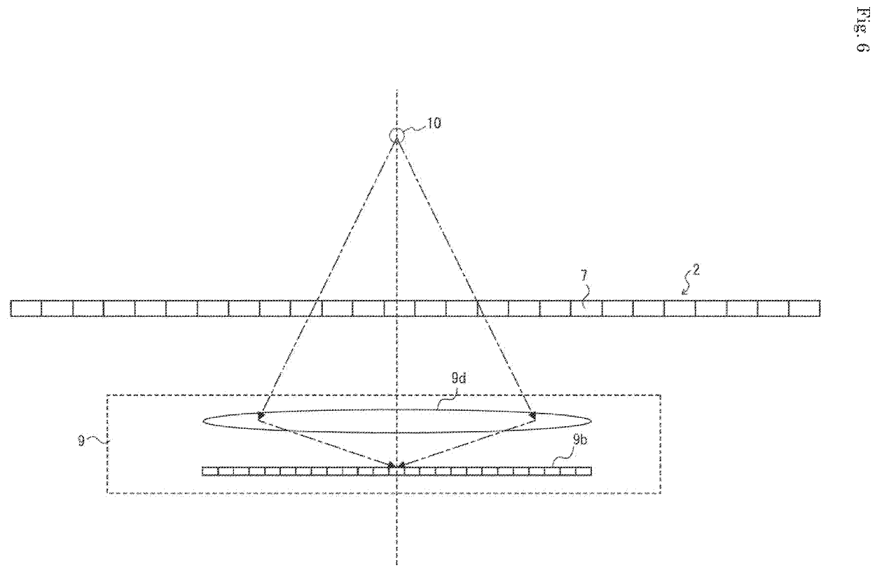

FIG. 5 is an explanatory drawing schematically illustrating the optical configuration of the image sensor module 9. Light from a subject 10 is refracted through the lens unit 9d and forms an image on the image sensor 9b. The larger the amount of incident light passing through the lens unit 9d, the larger the amount of light received by the image sensor 9b, leading to higher sensitivity.

In the present embodiment, the display panel 2 is disposed between the subject 10 and the lens unit 9d. It is significant to suppress absorption, reflection, and diffraction on the display panel 2 when light from the subject 10 passes through the display panel 2.

FIG. 6 is an explanatory drawing illustrating an optical path where light from the subject 10 forms an image on the image sensor 9b. In FIG. 6, the pixels 7 of the display panel 2 and the pixels 7 of the image sensor 9b are schematically illustrated as squares. As illustrated in FIG. 6, the pixels 7 of the display panel 2 are considerably larger than the pixels 7 of the image sensor 9b. Light from a specific position of the subject 10 passes through the transmissive window 6d of the display panel 2, is refracted through the lens unit 9d of the image sensor module 9, and forms an image at the specific pixel 7 on the image sensor 9b. In this way, light from the subject 10 passes through the transmissive windows 6d provided for the pixels 7 in the first pixel region 6 of the display panel 2 and enters the image sensor module 9.

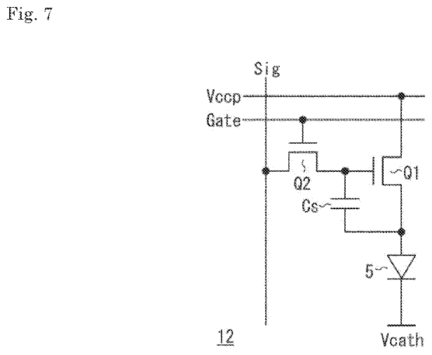

FIG. 7 is a circuit diagram of the basic configuration of a pixel circuit 12 including an OLED 5. The pixel circuit 12 of FIG. 7 includes a drive transistor Q1, a sampling transistor Q2, and a pixel capacitor Cs in addition to the OLED 5. The sampling transistor Q2 is connected between a signal line Sig and the gate of the drive transistor Q1. A scanning line Gate is connected to the gate of the sampling transistor Q2. The pixel capacitor Cs is connected between the gate of the drive transistor Q1 and the anode electrode of the OLED 5. The drive transistor Q1 is connected between a power-supply voltage node Vccp and the anode of the OLED 5.

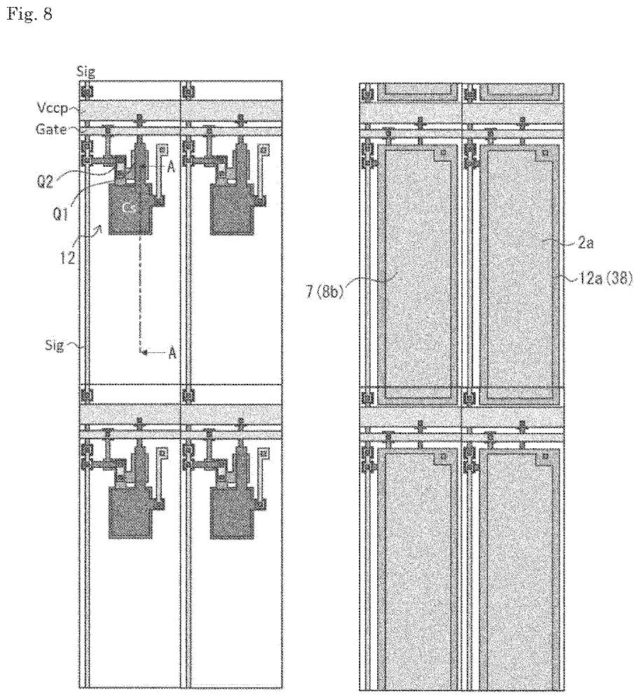

FIG. 8 is a plan layout of the pixels 7 in the second pixel region 8 that is not disposed directly above the sensors 5. The pixels 7 in the second pixel region 8 have typical pixel configurations. The pixels 7 each include multiple color pixels 7 (e.g., the three color pixels 7 of RGB). FIG. 8 illustrates the plan layout of the four color pixels 7: the two horizontal color pixels 7 and the two vertical color pixels 7. Each of the color pixels 7 includes the second luminous region 8b.

The second luminous region 8b extends substantially over the color pixel 7. In the second luminous region 8b, the pixel circuit 12 including the second self-emitting device 8a (OLED 5) is disposed. Two columns on the left side of FIG. 8 illustrate a plan layout under anode electrodes 12a, whereas two columns on the right side of FIG. 8 illustrate the plan layout of the anode electrodes 12a and display layers 2a disposed on the anode electrodes 12a.

As illustrated in the two columns on the right side of FIG. 8, the anode electrode 12a and the display layer 2a are disposed substantially over the color pixel 7. The entire region of the color pixel 7 serves as the second luminous region 8b.

As illustrate in the two columns on the left side of FIG. 8, the pixel circuit 12 of the color pixel 7 is disposed in the upper half region of the color pixel 7. On the upper end of the color pixel 7, a wiring pattern for a power-supply voltage Vccp and a wiring pattern for a scanning line are disposed in a horizontal direction X. Furthermore, a wiring pattern for the signal line Sig is disposed along the border of a vertical direction Y of the color pixel 7.

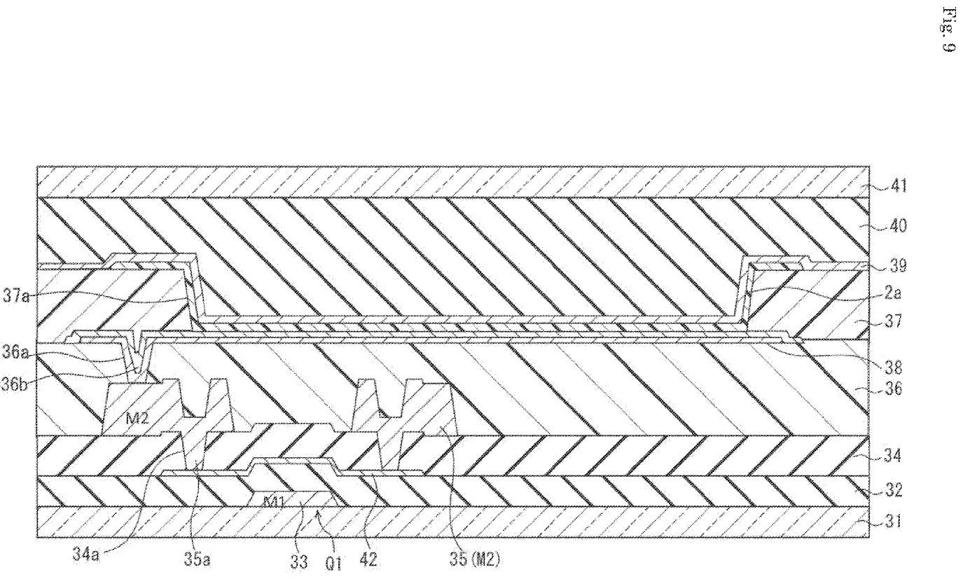

FIG. 9 is a cross-sectional view of the pixel 7 (color pixel 7) in the second pixel region 8 that is not disposed directly above the sensor 5. FIG. 9 illustrates a cross-sectional structure taken along line A-A of FIG. 8. More specifically, FIG. 9 illustrates a cross-sectional structure around the drive transistor Q1 in the pixel circuit 12. Cross-sectional views including FIG. 9 in the accompanying drawings of the present specification emphasize the characteristic layer configurations, and thus the length-to-width ratios do not always agree with the plan layout.

The top surface of FIG. 9 is the display-surface side of the display panel 2, and the bottom of FIG. 9 is a side where the sensor 5 is disposed. From the bottom side to the top-surface side (light emission side) of FIG. 9, a first transparent substrate 31, a first insulating layer 32, a first wiring layer (gate electrode) 33, a second insulating layer 34, a second wiring layer (source wiring or drain wiring) 35, a third insulating layer 36, an anode electrode layer 38, a fourth insulating layer 37, the display layer 2a, a cathode electrode layer 39, a fifth insulating layer 40, and a second transparent substrate 41 are sequentially stacked.

The first transparent substrate 31 and the second transparent substrate 41 are desirably composed of, for example, quartz glass or a transparent film with high transmission of visible light. Alternatively, one of the first transparent substrate 31 and the second transparent substrate 41 may be composed of quartz glass and the other may be composed of a transparent film.

In view of manufacturing, a colored and less transmissive film, e.g., a polyimide film may be used. Alternatively, at least one of the first transparent substrate 31 and the second transparent substrate 41 may be composed of a transparent film. On the first transparent substrate 31, a first wiring layer (M1) 33 is disposed to connect the circuit elements in the pixel circuit 12.

On the first transparent substrate 31, the first insulating layer 32 is disposed over the first wiring layer 33. The first insulating layer 32 is, for example, a laminated structure of a silicon nitride layer and a silicon oxide layer with high transmission of visible light. On the first insulating layer 32, a semiconductor layer 42 is disposed with a channel region formed for the transistors in the pixel circuit 12. FIG. 9 schematically illustrates a cross-sectional structure of the drive transistor Q1 including the gate formed in the first wiring layer 33, the source and drain formed in the second wiring layer 35, and the channel region formed in the semiconductor layer 42. The other transistors are also disposed in the layers 33, 35, and 42 and are connected to the first wiring layer 33 via contacts, which are not illustrated.

On the first insulating layer 32, the second insulating layer 34 is disposed over the transistors or the like. The second insulating layer 34 is, for example, a laminated structure of a silicon oxide layer, a silicon nitride layer, and a silicon oxide layer with high transmission of visible light. In a part of the second insulating layer 34, a trench 34a is formed and is filled with a contact member 35a, so that a second wiring layer (M2) 35 connected to the sources and drains of the transistors is formed in the trench 34a. FIG. 9 illustrates the second wiring layer 35 connecting the drive transistor Q1 and the anode electrode 12a of the OLED 5. The second wiring layer 35 connected to the other circuit elements is also disposed in the same layer. As will be described later, a third wiring layer, which is not illustrated, may be provided between the second wiring layer 35 and the anode electrode 12a in FIG. 9. The third wiring layer may be used for connection to the anode electrode 12a as well as wiring in the pixel circuit.

On the second insulating layer 34, the third insulating layer 36 for covering the second wiring layer 35 to form a flat surface is disposed. The third insulating layer 36 is made of a resin material, e.g., acrylic resin. The third insulating layer 36 has a larger thickness than the first and second insulating layers 32 and 34.

On a part of the top surface of the third insulating layer 36, a trench 36a is formed and is filled with a contact member 36b to make an electrical connection to the second wiring layer 35. The contact member 36b is extended to the top surface of the third insulating layer 36 and forms the anode electrode layer 38. The anode electrode layer 38 has a laminated structure including a metallic material layer. The metallic material layer typically has a low transmittance of visible light and acts as a reflective layer that reflects light. A specific metallic material may be, for example, AlNd or Ag.

The bottom layer of the anode electrode layer 38 is in contact with the trench 36a and is prone to break. Thus, in some cases, at least the corners of the trench 36a are made of a metallic material, e.g., AlNd. The uppermost layer of the anode electrode layer 38 is composed of a transparent conductive layer made of ITO (Indium Tin Oxide) or the like. Alternatively, the anode electrode layer 38 may have a laminated structure of, for example, ITO/Ag/ITO. Ag is originally opaque but the transmittance of visible light is increased by reducing the film thickness. Since Ag with a small thickness leads to lower strength, the laminated structure with ITO on both sides can act as a transparent conductive layer.

On the third insulating layer 36, the fourth insulating layer 37 is disposed over the anode electrode layer 38. The fourth insulating layer 37 is also made of a resin material, e.g., acrylic resin like the third insulating layer 36. The fourth insulating layer 37 is patterned according to the location of the OLED 5 and has a recessed portion 37a.

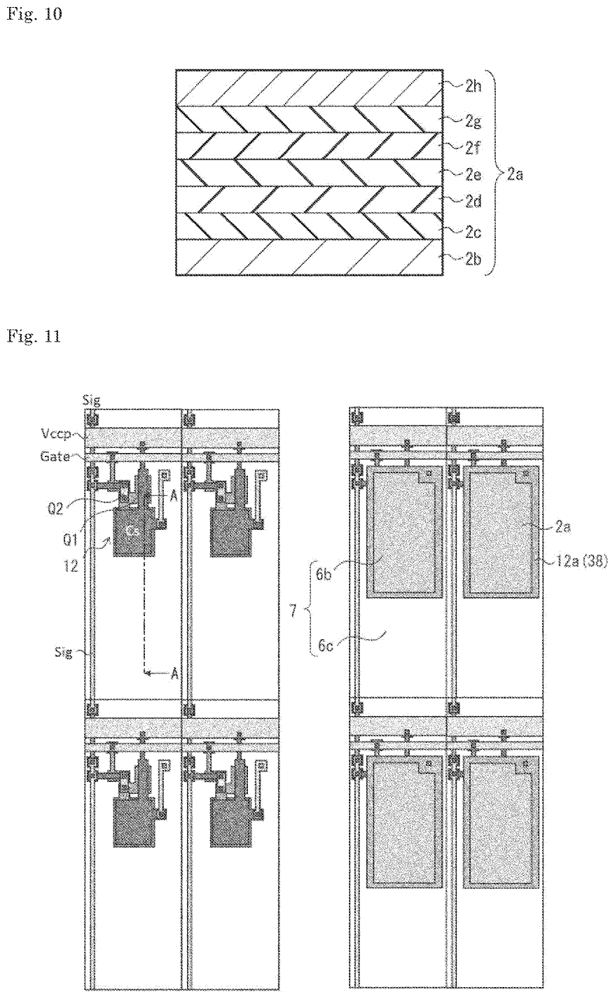

The display layer 2a is disposed so as to include the bottom and the sides of the recessed portion 37a of the fourth insulating layer 37. For example, the display layer 2a has a laminated structure illustrated in FIG. 10. The display layer 2a in FIG. 10 is a laminated structure in which an anode 2b, a hole injection layer 2c, a hole transport layer 2d, a luminescent layer 2e, an electron transport layer 2f, an electron injection layer 2g, and a cathode 2h are disposed in the order of stacking from the anode electrode layer 38. The anode 2b is also called the anode electrode 12a. The hole injection layer 2c is a layer to which a hole is injected from the anode electrode 12a. The hole transport layer 2d is a layer that efficiently transports a hole to the luminescent layer 2e. The luminescent layer 2e recombines a hole and an electron to generate an exciton and emits light when the exciton returns to a ground state. The cathode 2h is also called a cathode electrode. The electron injection layer 2g is a layer to which an electron is injected from the cathode 2h. The electron transport layer 2f is a layer that efficiently transports an electron to the luminescent layer 2e. The luminescent layer 2e contains an organic substance.

The cathode electrode layer 39 is disposed on the display layer 2a illustrated in FIG. 9. The cathode electrode layer 39 includes a transparent conductive layer like the anode electrode layer 38. The transparent conductive layer of the anode electrode layer 38 is made of, for example, ITO/Ag/ITO, whereas the transparent electrode layer of the cathode electrode layer 39 is made of, for example, MgAg.

The fifth insulating layer 40 is disposed on the cathode electrode layer 39. The fifth insulating layer 40 has a flat top surface and is made of an insulating material having high moisture resistance. On the fifth insulating layer 40, the second transparent substrate 41 is disposed.

As illustrated in FIGS. 8 and 9, in the second pixel region 8, the anode electrode layer 38 acting as a reflective film is disposed substantially over the color pixel 7, thereby preventing the passage of visible light.

FIG. 11 is a plan layout of the pixels 7 in the first pixel regions 6 that are disposed directly above the sensors 5. The pixels 7 each include multiple color pixels 7 (e.g., the three color pixels 7 of RGB). FIG. 11 illustrates the plan layout of the four color pixels 7: the two horizontal color pixels 7 and the two vertical color pixels 7. Each of the color pixels 7 includes the first luminous region 6b and the nonluminous region 6c. The first luminous region 6b is a region that includes the pixel circuit 12 having the first self-emitting device 6a (OLED 5) and is illuminated by the OLED 5. The nonluminous region 6c is a region that passes visible light.

The nonluminous region 6c cannot emit light from the OLED 5 but can pass incident visible light. Thus, the sensor 5 disposed immediately under the nonluminous region 6c can receive visible light.

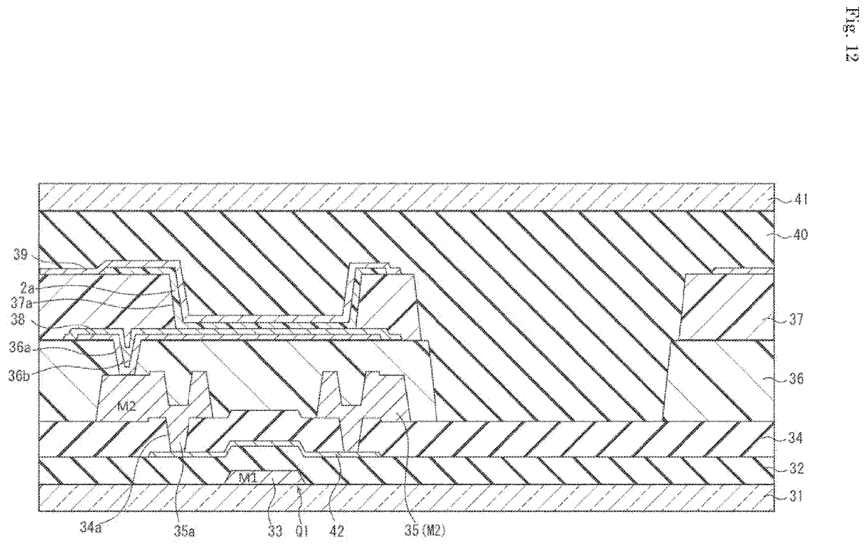

FIG. 12 is a cross-sectional view of the pixel 7 in the first pixel region 6 that is disposed directly above the sensor 5. FIG. 12 illustrates a cross-sectional structure taken along line A-A of FIG. 11, from the first luminous region 6b to the nonluminous region 6c. In comparison with FIG. 9, the third insulating layer 36, the fourth insulating layer 37, the anode electrode layer 38, the display layer 2a, and the cathode electrode layer 39 are removed in the nonluminous region 6c. Thus, light entering the nonluminous region 6c from above (display surface) in FIG. 12 is emitted from the bottom (backside) and enters the sensor 5 without being absorbed or reflected in the nonluminous region 6c.

However, incident light in the first pixel region 6 is partially passed through the first luminous region 6b in addition to the nonluminous region 6c and is diffracted therein, causing diffracted light.

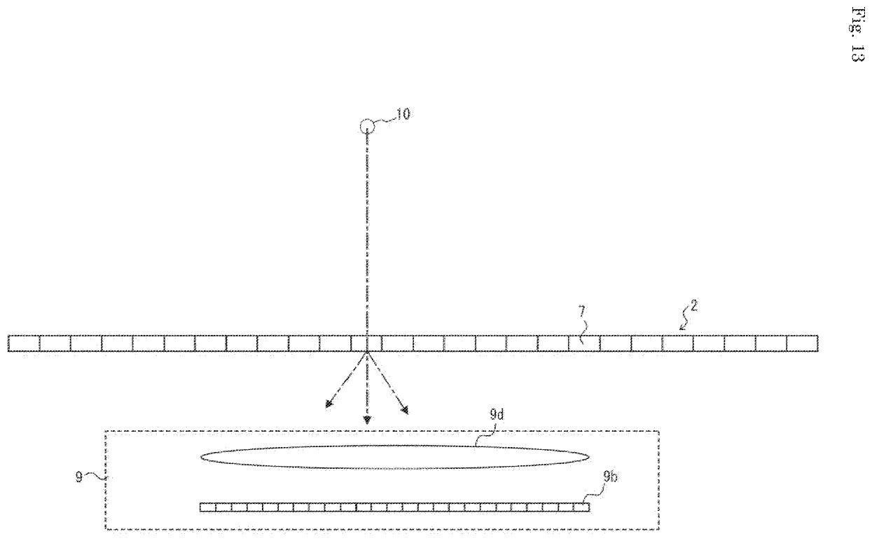

FIG. 13 is an explanatory drawing of a diffraction phenomenon that generates diffracted light. Parallel rays such as sunlight and light having high directivity are diffracted at, for example, a boundary portion between the nonluminous region 6c and the first luminous region 6b and generate high-order diffracted light such as primary diffracted light. Zeroth-order diffracted light is light passing along the optical axis of incident light and has the highest intensity among diffracted light.

In other words, zeroth-order diffracted light is an object to be imaged, that is, light to be imaged. Diffracted light of a higher order passes in a direction apart from zeroth-order diffracted light and decreases in light intensity. Generally, high-order diffracted light including primary diffracted light is collectively called diffracted light. Diffracted light is light that is not supposed to be present in subject light and is unnecessary for imaging the subject 10.

In a captured image including diffracted light, the brightest point is zeroth-order light. High-order diffracted light extends in the shape of a cross from zeroth-order diffracted light. When subject light is white light, diffraction angles vary among wavelength components included in the white light, so that rainbow-colored diffracted light f is generated.

For example, diffracted light in a captured image is cross-shaped. The shape of the diffracted light f depends upon the shape of a portion that passes light in the nonluminous region 6c as will be described later. If the portion that passes light has a known shape, the shape of diffracted light can be estimated by simulation from the principle of diffraction. In the plan layout of the pixels 7 in the first pixel regions 6 in FIG. 11, a light transmission region is also present in a gap between wirings and around the first luminous region 6b, except for the nonluminous region 6c. The light transmission regions having irregular shapes at multiple points in the pixel 7 may diffract incident light in a complicated manner, so that the diffracted light f may have a complicated shape.

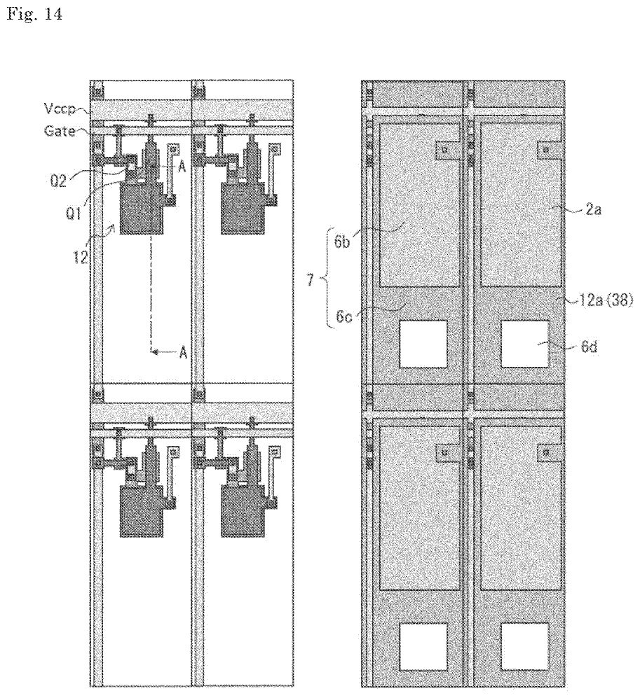

FIG. 14 is a plan layout of the image display device 1 according to an embodiment that solves the problem in the plan layout of FIG. 11. In FIG. 14, the anode electrode 12a is disposed over the first luminous region 6b in the first pixel region 6 so as to block light, and the transmissive window 6d in a predetermined shape is provided in the nonluminous region 6c, so that subject light passes only through the transmissive window 6d. In the example of FIG. 14, the anode electrode 12a surrounds the transmissive window 6d of the nonluminous region 6c. As will be described later, a member that determines the shape of the transmissive window 6d is not always limited to the anode electrodes 12a.

In FIG. 14, the transmissive window 6d is rectangular in plan view. The planar shape of the transmissive window 6d is desirably simplified as much as possible. The simple shape simplifies the direction of generation of the diffracted light f, so that the shape of diffracted light can be determined in advance by simulation.

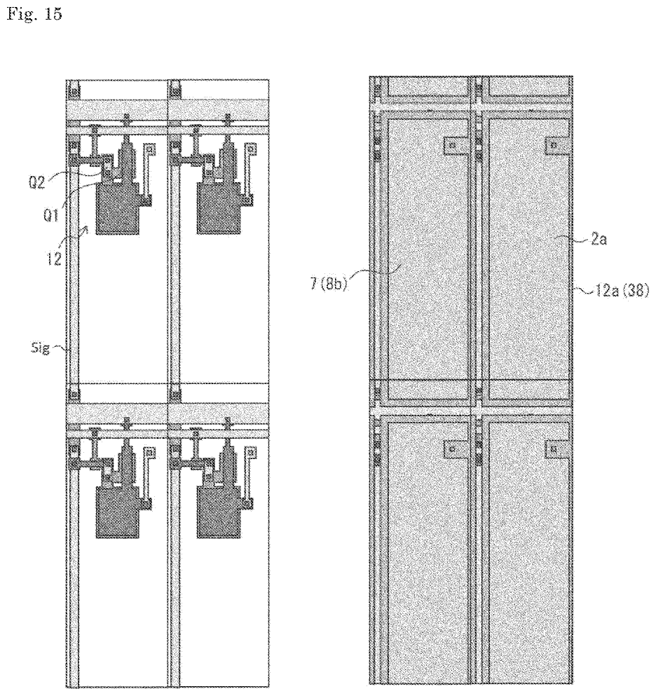

As described above, according to the present embodiment, the first pixel region 6 located directly above the sensor 5 in the display panel 2 is provided with the transmissive window 6d in the nonluminous region 6c in the pixel 7 as illustrated in FIG. 14, so that the shape of the diffracted light f is controlled. In contrast, the second pixel region 8 not located directly above the sensor 5 in the display panel 2 may have the same plan layout as FIG. 8. Alternatively, as illustrated in FIG. 15, the anode electrode 12a may be disposed over the second luminous region 8b in the pixel 7 so as to block incident light. The anode electrode 12a having a large area extends a luminous area, thereby suppressing deterioration of the OLED 5. Thus, the plan layout of FIG. 15 is more desirable than FIG. 8.

As described above, the shape of the transmissive window 6d in the nonluminous region 6c in the first pixel region 6 disposed directly above the sensor 5 can be determined by any one of multiple members.

FIG. 16 is a cross-sectional view illustrating a first example of the cross-sectional structure of the first pixel region 6. In the example of FIG. 16, the shape of the transmissive window 6d in the nonluminous region 6c is determined by the anode electrode 12a (anode electrode layer 38). As illustrated in FIG. 14, the ends of the anode electrode layer 38 are rectangular in plan view when viewed from the display surface side. In this way, in the example of FIG. 16, the shape of the transmissive window 6d is determined by the ends of the anode electrode layer 38.

In the example of FIG. 16, the third insulating layer 36 and the fourth insulating layer 37 in the transmissive window 6d are left as they are. Thus, if the third insulating layer 36 and the fourth insulating layer 37 are composed of colored resin layers, the transmittance of visible light may decrease, but the third insulating layer 36 and the fourth insulating layer 37 in the transmissive window 6d may be left because at least part of visible light passes through the transmissive window 6d.

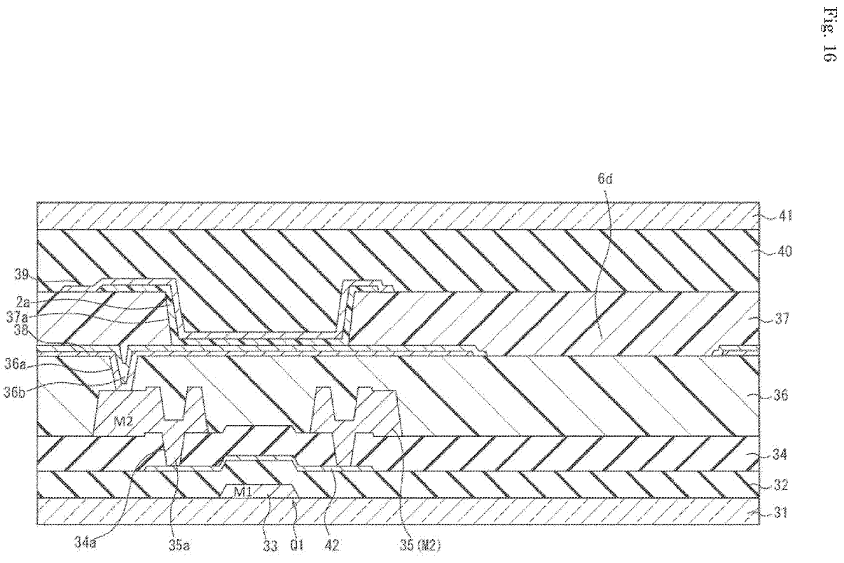

FIG. 17 is a cross-sectional view illustrating a second example of the cross-sectional structure of the first pixel region 6. In FIG. 17, the shape of the transmissive window 6d is determined by the ends of the anode electrode layer 38 as in FIG. 16. FIG. 17 is different from FIG. 16 in that the fourth insulating layer 37 is removed in the transmissive window 6d. Since the fourth insulating layer 37 is not present in the transmissive window 6d, the absorption and reflection of light passing through the fourth insulating layer 37 can be suppressed to increase the amount of light incident on the sensor 5, so that the sensor 5 can have higher sensitivity to received light.

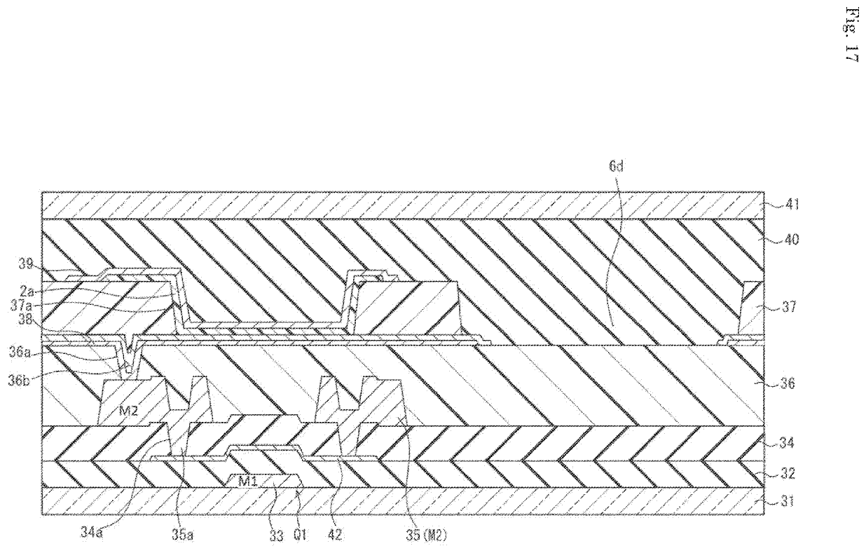

FIG. 18 is a cross-sectional view illustrating a third example of the cross-sectional structure of the first pixel region 6. In FIG. 18, the shape of the transmissive window 6d is determined by the ends of the anode electrode layer 38 as in FIGS. 16 and 17. FIG. 18 is different from FIGS. 16 and 17 in that the third insulating layer 36 and the fourth insulating layer 37 are removed in the transmissive window 6d. Since the third and fourth insulating layers 36 and 37 are not present in the transmissive window 6d, the amount of light incident on the sensor 5 can be larger than that of FIG. 17, so that the sensor 5 can have higher sensitivity to received light than in FIG. 17.

In FIG. 18, the ends of the third insulating layer 36 disposed under the anode electrode layer 38 are located substantially at the same positions as the ends of the anode electrode layer 38. The ends of the third insulating layer 36 may protrude from the ends of the anode electrode layer 38 into the transmissive window 6d depending upon variations in production. In this case, it is uncertain whether the shape of the transmissive window 6d is determined by the ends of the anode electrode layer 38 or the ends of the third insulating layer 36. Furthermore, the occurrence of the diffracted light f may be changed according to the degree of protrusion of the ends of the third insulating layer 36.

Hence, as will be described below, the shape of the transmissive window 6d may be determined by the wiring layer at the bottom side under the third insulating layer 36.

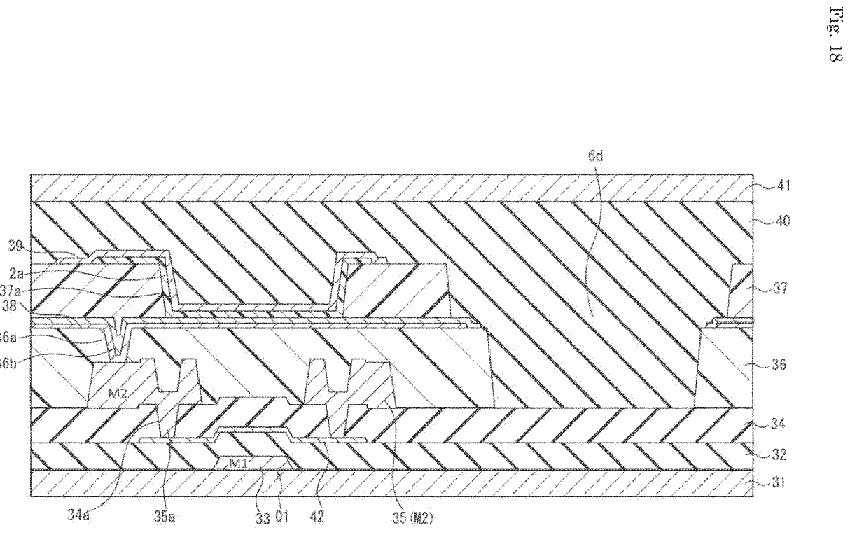

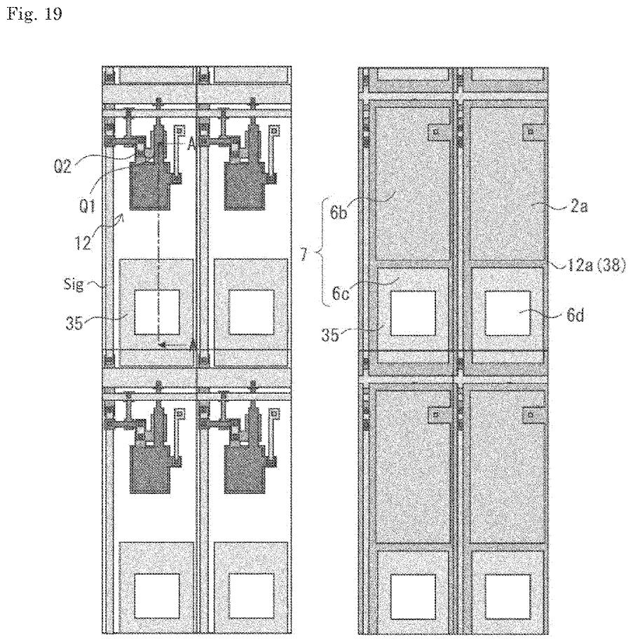

FIG. 19 illustrates a plan layout according to a first modification of FIG. 14. FIG. 20 is a cross-sectional view taken along line A-A of FIG. 19. FIG. 20 illustrates a fourth example of the cross-sectional structure of the first pixel region 6. In the example of FIGS. 19 and 20, the shape of the transmissive window 6d is determined by the ends of the second wiring layer (M2) 35 disposed under the third insulating layer 36. As illustrated in FIG. 19, the second wiring layer (M2) 35 is rectangular in plan view when viewed from the display surface. Since the second wiring layer (M2) 35 is made of a metallic material, e.g., aluminum that blocks visible light, incident light in the first pixel region 6 passes through the transmissive window 6d and enters the sensor 5.

In the cross-sectional structure of FIG. 19, the second wiring layer (M2) 35 is extended into the transmissive window 6d more than the third insulating layer 36, allowing the second wiring layer (M2) 35 to determine the shape of the transmissive window 6d even if variations in production are shown.

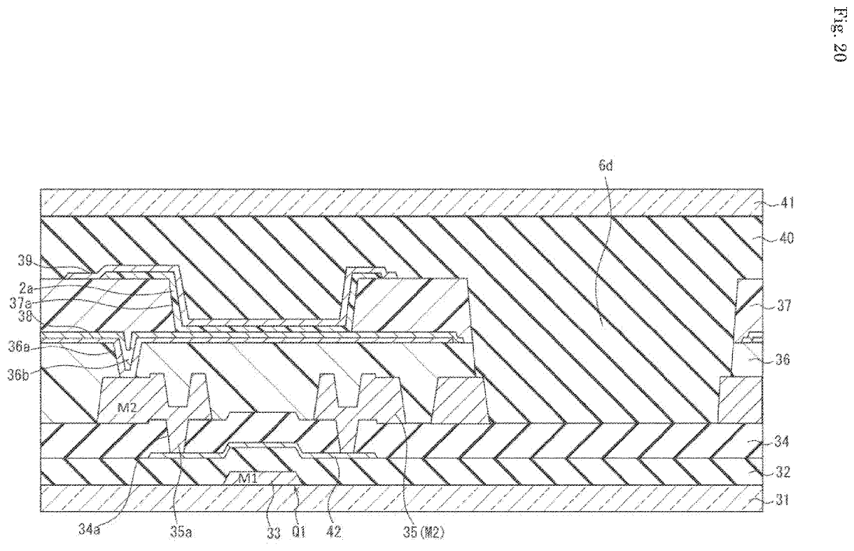

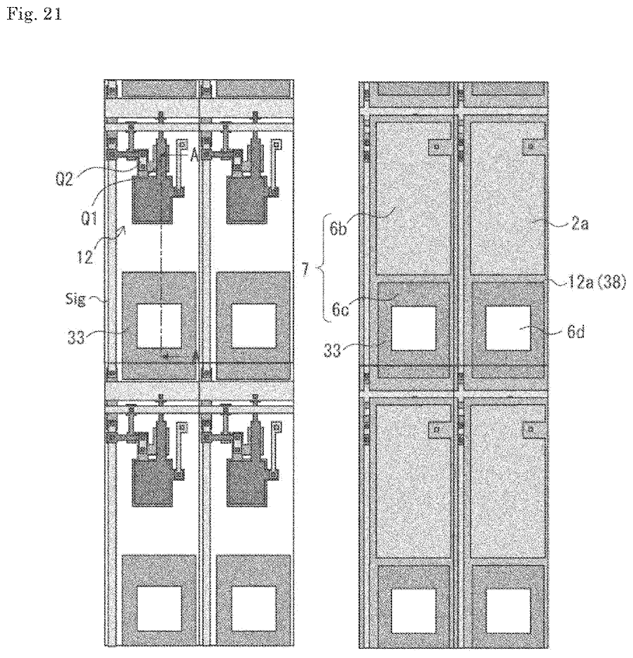

FIG. 21 illustrates a plan layout according to a second modification of FIG. 14. FIG. 22 is a cross-sectional view taken along line A-A of FIG. 21. In the example of FIGS. 21 and 22, the shape of the transmissive window 6d is determined by the ends of the first wiring layer (M1) 33 disposed under the third insulating layer 36. As illustrated in FIG. 21, the first wiring layer (M1) 33 is rectangular in plan view when viewed from the display surface. Since the first wiring layer (M1) 33 is made of a metallic material, e.g., aluminum that blocks visible light, incident light in the first pixel region 6 passes through the transmissive window 6d and enters the sensor 5.

In the examples of FIGS. 19 to 22, the shape of the transmissive window 6d is determined by the ends of the wiring layer. The wiring layer that determines the shape of the transmissive window 6d may form a capacitor. This eliminates the need for additionally forming a capacitor, thereby simplifying the cross-sectional structure of the image display device 1.

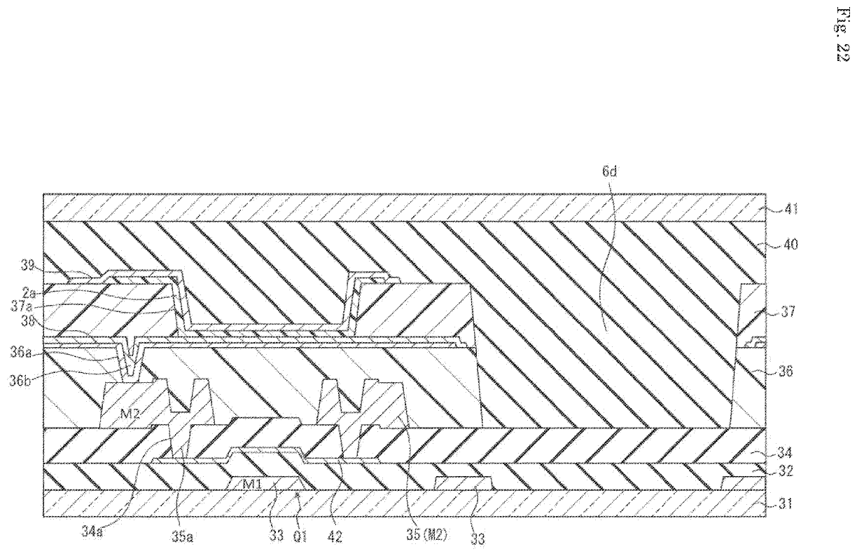

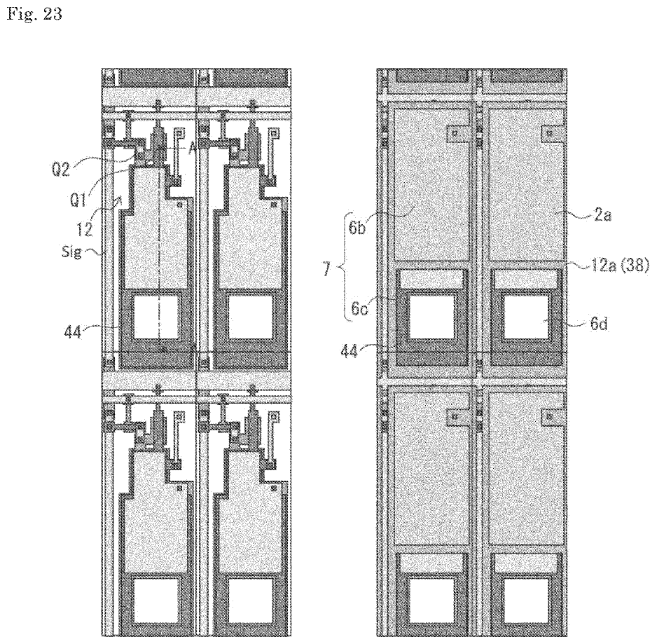

FIG. 23 illustrates a plan layout according to a third modification of FIG. 14. FIG. 24 is a cross-sectional view taken along line A-A of FIG. 23. In FIG. 24, the shape of the transmissive window 6d is determined by the first wiring layer (M1) 33. Directly above the first wiring layer (M1) 33 provided to determine the shape of the transmissive window 6d, a metallic layer 44 is disposed to form a capacitor 43 with the first insulating layer 32 interposed between the first wiring layer (M1) 33 and the metallic layer 44. The capacitor 43 can be used as a capacitor provided for the pixel circuit 12. The capacitor 43 in FIG. 24 can be used as, for example, the pixel capacitor Cs in the pixel circuit 12 of FIG. 7.

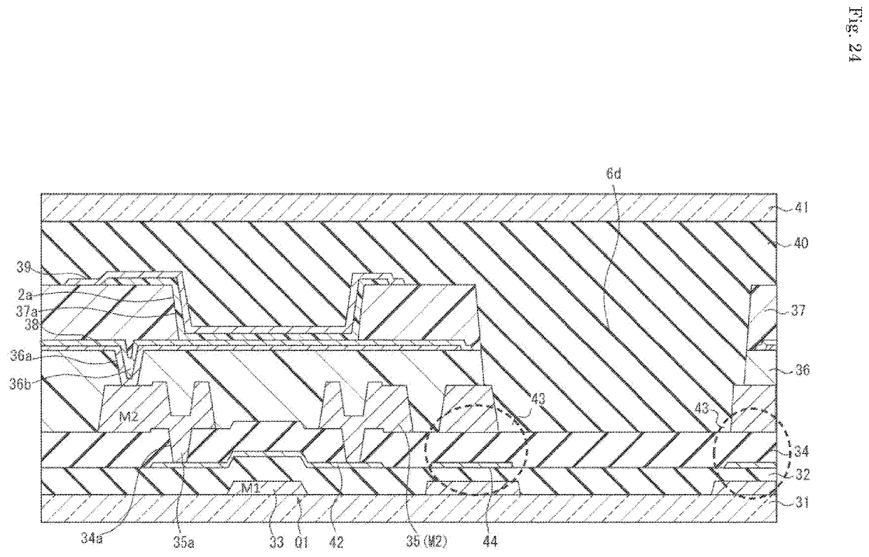

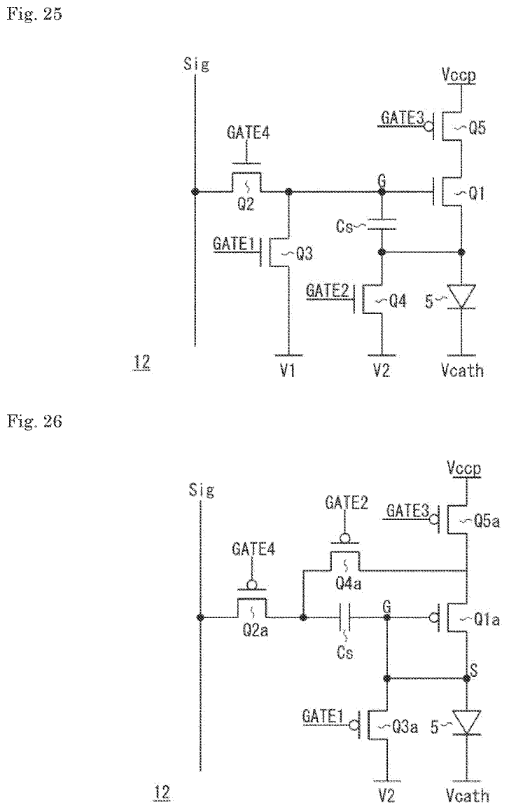

FIG. 25 is a circuit diagram showing a first example of the detailed circuit configuration of the pixel circuit 12. The pixel circuit 12 in FIG. 25 includes three transistors Q3 to Q5 in addition to the drive transistor Q1 and the sampling transistor Q2 in FIG. 7. The drain of the transistor Q3 is connected to the gate of the drive transistor Q1, the source of the transistor Q3 is set at a voltage V1, and the gate of the transistor Q3 receives a gate signal Gate1. The drain of the transistor Q4 is connected to the anode electrode 12a of the OLED 5, the source of the transistor Q4 is set at a voltage V2, and the gate of the transistor Q4 receives a gate signal Gate2.

The transistors Q1 to Q4 are N-type transistors, whereas the transistor Q5 is a P-type transistor. The source of the transistor Q5 is set at the power-supply voltage Vccp, the drain of the drive transistor Q5 is connected to the drain of the drive transistor Q1, and the gate of the transistor Q5 receives a gate signal Gate3.

FIG. 26 is a circuit diagram showing a second example of the detailed circuit configuration of the pixel circuit 12. The conductivity types of transistors Q1a to Q5a in the pixel circuit 12 of FIG. 26 are inverted from those of the transistors Q1 to Q5 in the pixel circuit 12 of FIG. 25. In addition to the inverted conductivity types of the transistors, the circuit configuration of the pixel circuit 12 of FIG. 26 is partially different from that of the pixel circuit 12 of FIG. 25. FIGS. 25 and 26 merely illustrate examples of the pixel circuit 12. The circuit configuration may be changed in various manners.

The capacitor 43 formed by the first wiring layer (M1) 33 and the metallic layer disposed directly above the first wiring layer (M1) 33 in FIG. 24 can be used as a capacitor Cs in the pixel circuit 12 of FIG. 25 or 26.

In FIGS. 19 to 26, the wiring layer constituting a part of the pixel circuit 12 is used to determine the shape of the transmissive window 6d. A metallic layer for determining the shape of the transmissive window 6d may be provided in addition to the wiring layer of the pixel circuit 12.

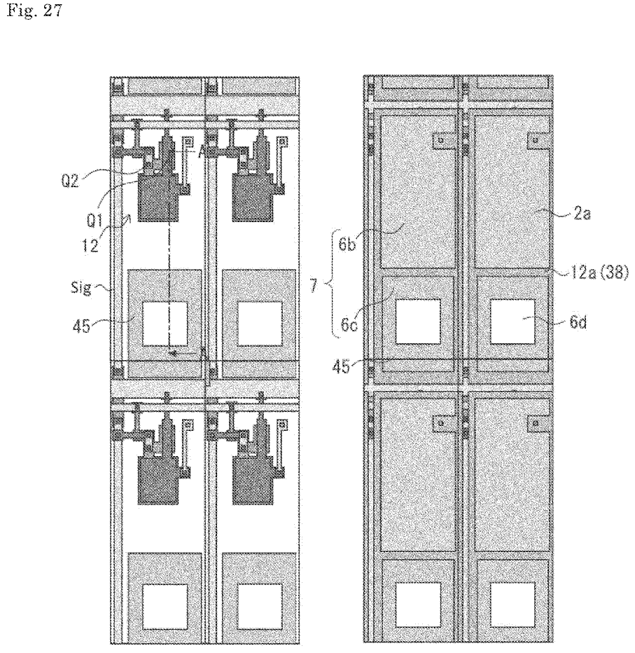

FIG. 27 illustrates a plan layout according to a fourth modification of FIG. 14. FIG. 28 is a cross-sectional view taken along line A-A of FIG. 27. In FIG. 28, the shape of the transmissive window 6d is determined by the ends of a third metallic layer (M3) 45. The third metallic layer (M3) 45 for determining the shape of the transmissive window 6d may constitute a part of the wiring layer of the pixel circuit 12 or may be additionally provided for determining the shape of the transmissive window 6d. Patterns provided for determining the opening shapes of FIGS. 19, 21, and 27 are illustrated as electrically floating images and are susceptible to an electrical impact, e.g., potential coupling. Thus, a connection to any potential is recommended. For example, in FIG. 25, a fixed DC potential (Vccp, Vcath, V1, V2) is a first recommendation, an anode potential is a second recommendation, and other wires and nodes are a third recommendation.

The first wiring layer (M1) 33 and the second wiring layer (M2) 35 that are used as the wirings of the pixel circuit 12 are restricted as the wirings of the pixel circuit 12 and thus may be disposed so as not to match the ideal shape of the transmissive window 6d. Thus, in FIG. 27, the third wiring layer (M3) 45 is additionally provided. The ends of the third wiring layer (M3) 45 are disposed to form the ideal shape of the transmissive window 6d. This configuration can set the transmissive window 6d in the ideal shape without changing the first wiring layer (M1) 33 or the second wiring layer (M2) 35.

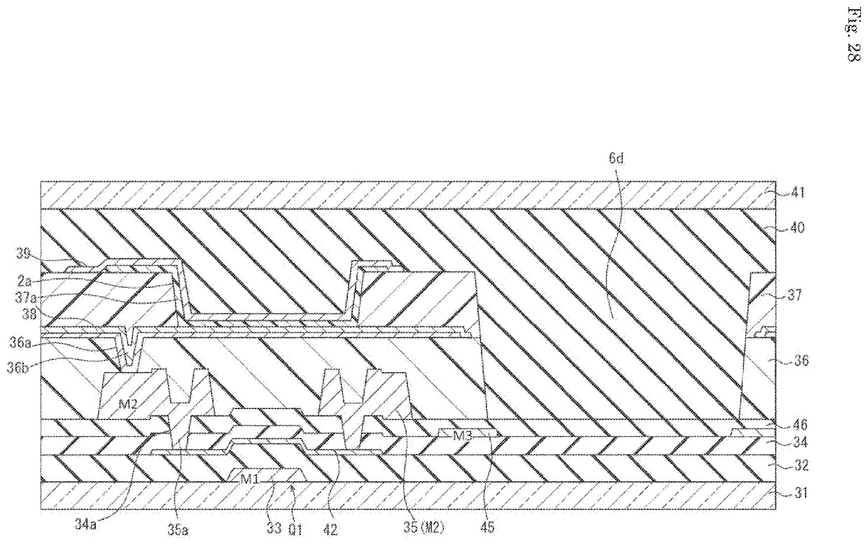

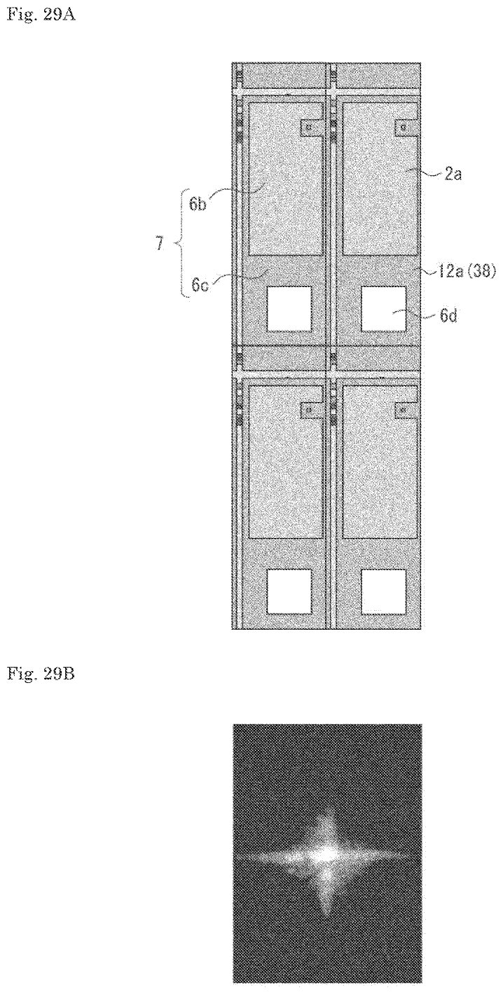

In the foregoing examples, the transmissive window 6d is rectangular. The shape of the transmissive window 6d is not limited to a rectangle. However, the shape of the diffracted light f changes according to the shape of the transmissive window 6d. FIG. 29A illustrates an example in which the transmissive windows 6d are rectangular. FIG. 29B shows an example of the diffracted light f generated when parallel rays are projected into the transmissive window 6d of FIG. 29A. As shown in FIG. 29B, in the case of the rectangular transmissive window 6d, the diffracted light f is generated in the shape of a cross.

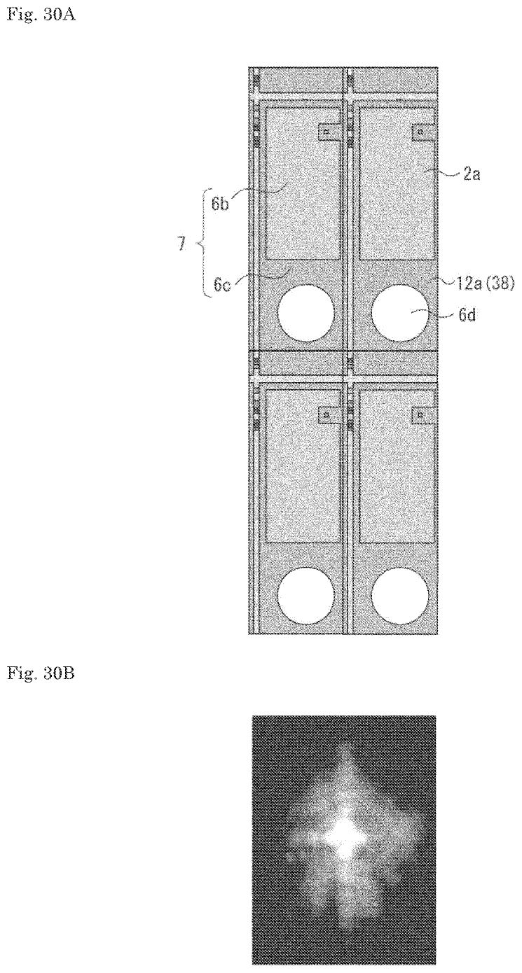

FIG. 30A illustrates an example in which the transmissive windows 6d are circular. FIG. 30B shows an example of the diffracted light f generated when parallel rays are projected into the transmissive window 6d of FIG. 30A. As shown in FIG. 30B, in the case of the circular transmissive window 6d, the diffracted light f is generated like a concentric circle. The higher-order diffracted light f has a larger diameter and lower light intensity.

The nonluminous region 6c does not always include the single transmissive window 6d. The nonluminous region 6c may include a plurality of transmissive windows 6d. FIG. 31A illustrates an example in which the plurality of circular transmissive windows 6d are provided in the nonluminous region 6c. FIG. 31B shows an example of the diffracted light f generated when parallel rays are projected into the transmissive windows 6d of FIG. 31A. The provision of the plurality of transmissive windows 6d reduces the light intensity of the central portion of the diffracted light f and concentrically generates the diffracted light f. In FIG. 31A, the circular transmissive windows 6d are provided. The transmissive windows 6d may be provided in other shapes. In this case, the shape of the diffracted light f is different from that of FIG. 31B.

As shown in FIGS. 29A and 29B, in the case of the rectangular transmissive window 6d, the diffracted light f is generated in the shape of a cross. In order to remove the diffracted light f through image processing by software, for example, the rectangular transmissive windows 6d may be provided in different orientations such that the diffracted light f generated in the transmissive windows 6d is combined to be removed.

FIG. 32 illustrates a first example of the removal of the diffracted light f. In FIG. 32, the two image sensor modules 9 are disposed immediately under the display panel 2, and the rectangular transmissive windows 6d in different orientations are disposed in the respective nonluminous regions 6c of the pixels 7 in the two first pixel regions 6 disposed directly above the image sensor modules 9.

In the example of FIG. 32, in the nonluminous region 6c in the first pixel region 6 disposed directly above the image sensor module 9 located on the left side, the rectangular transmissive window 6d is disposed substantially in parallel with the boundary of the pixel 7. In the nonluminous region 6c in the first pixel region 6 disposed directly above the image sensor module 9 located on the right side, the rectangular transmissive window 6d is disposed in a direction tilted at 45° with respect to the boundary of the pixel 7.

The cross shape of diffracted light f1 incident on the left image sensor module 9 and the cross shape of diffracted light f2 incident on the right image sensor module 9 are oriented in different directions at 45°. More specifically, the diffracted light f2 is not generated in the direction that generates the diffracted light f1, and the diffracted light f1 is not generated in the direction that generates the diffracted light f2. Thus, by synthesizing a captured image g1 of the diffracted light f1 by the left image sensor module 9 and a captured image g2 of the diffracted light f2 by the right image sensor module 9, the diffracted light f other than a light spot of zeroth-order diffracted light at the central position can be removed as indicated by a composite image g3 of FIG. 32.

In FIG. 32, the transmissive windows 6d identical in size and shape are disposed at different angles to generate the diffracted light f in different directions, so that the images of the generated diffracted light f are synthesized to cancel the diffracted light f. The transmissive windows 6d to be synthesized are not necessarily identical in size and shape.

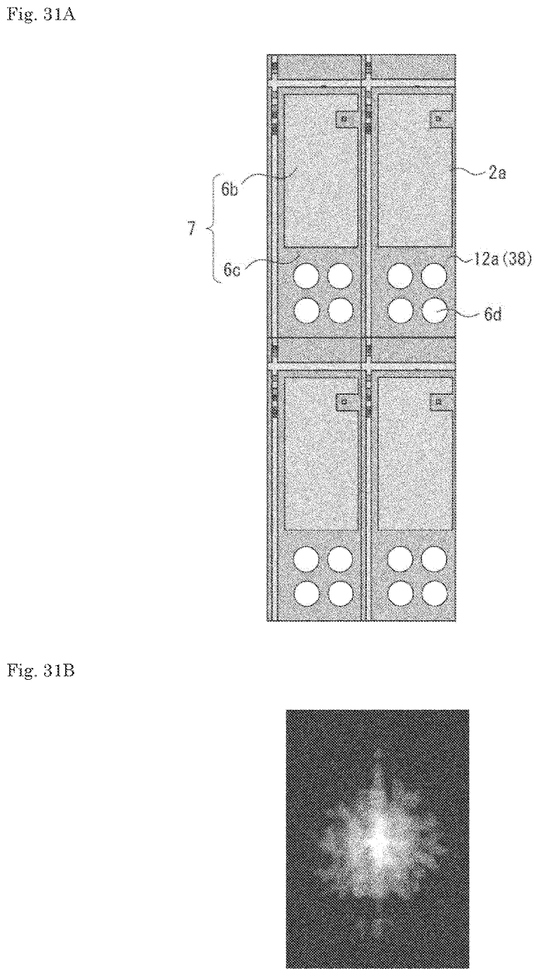

FIG. 33 illustrates a second example of the removal of the diffracted light f. In FIG. 33, the two image sensor modules 9 are disposed immediately under the display panel 2, and the transmissive windows 6d in different shapes and orientations are disposed in the respective two first pixel regions 6 disposed directly above the image sensor modules 9.

In the example of FIG. 33, the transmissive window 6d is provided substantially over the nonluminous region 6c in the first pixel region 6 disposed directly above the image sensor module 9 on the left side. Since the nonluminous region 6c is rectangular, the transmissive window 6d is also rectangular. In the nonluminous region 6c in the first pixel region 6 disposed directly above the image sensor module 9 on the right side, the transmissive window 6d smaller than the left first pixel region 6 is provided in a direction tilted 45° with respect to the boundary of the pixel 7.

As described above, in the example of FIG. 33, the different-sized transmissive windows 6d on the left side and the right side are tilted in different directions. The shapes of diffracted light f3 and f4 are substantially identical to those of the diffracted light f1 and f2 in FIG. 32 (captured images g4 and g5). Thus, as in FIG. 32, by synthesizing the images of the diffracted light f, the images being captured by the image sensors 9b, the diffracted light f other than a light spot of zeroth-order diffracted light can be removed as indicated by a composite image g6.

The foregoing embodiment described an example in which at least one transmissive window 6d is provided for each of the pixels 7 (or color pixels 7). One or more transmissive windows 6d may be provided for the plurality of pixels 7 (or color pixels 7).

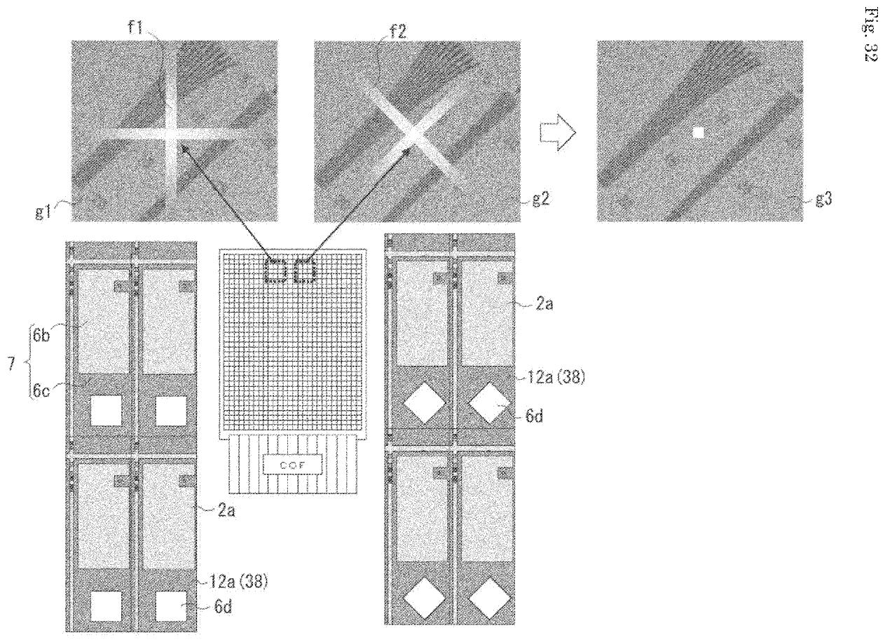

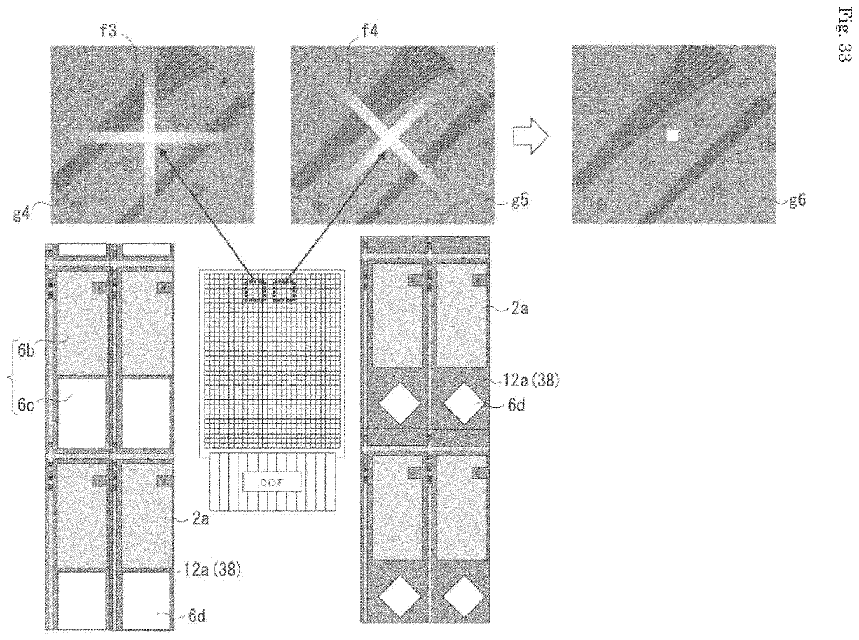

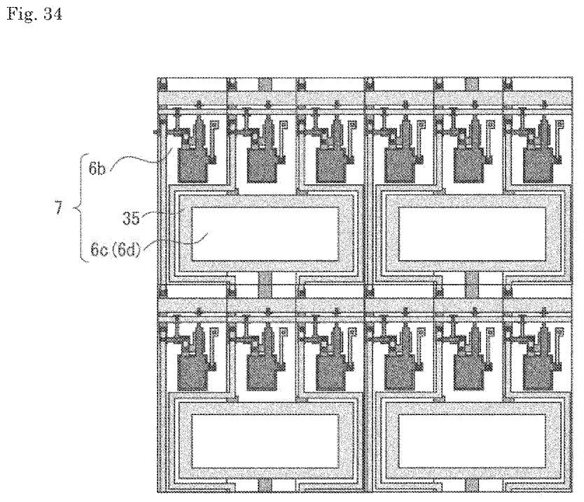

FIG. 34 illustrates an example of the single transmissive window 6d provided over the three pixels 7 (or three color pixels 7). In FIG. 34, the shape of the transmissive window 6d is determined by, for example, the ends of the second wiring layer (M2) 35.

FIG. 35 illustrates a third example of the removal of the diffracted light f. In FIG. 35, the two image sensor modules 9 are disposed immediately under the display panel 2, and the transmissive windows 6d in different shapes and orientations are disposed in the respective nonluminous regions 6c of the pixels 7 in the two first pixel regions 6 disposed directly above the image sensor modules 9.

In the example of FIG. 35, in the nonluminous region 6c in the first pixel region 6 disposed directly above the image sensor module 9 on the left side, the rectangular transmissive window 6d is sized to extend over the three pixels 7 (or three color pixels 7). In the nonluminous region 6c in the first pixel region 6 disposed directly above the image sensor module 9 on the right side, the three transmissive windows 6d smaller than the first pixel region 6 on the left side are provided over the three pixels 7 (or three color pixels 7) in a direction tilted 45° with respect to the boundary of the pixel 7. Also in FIG. 35, generated diffracted light f5 and f6 is substantially identical to the diffracted light f1 and f2 in FIG. 32 (captured images g7 and g8).

In the foregoing examples, the direction of generation of the diffracted light f can be predicted by providing the transmissive window 6d in the nonluminous region 6c in the first pixel region 6. The sensor 5 can receive only light having passed through the transmissive window 6d. This may limit the amount of light received by the sensor 5 and reduce the detection sensitivity of the sensor 5.

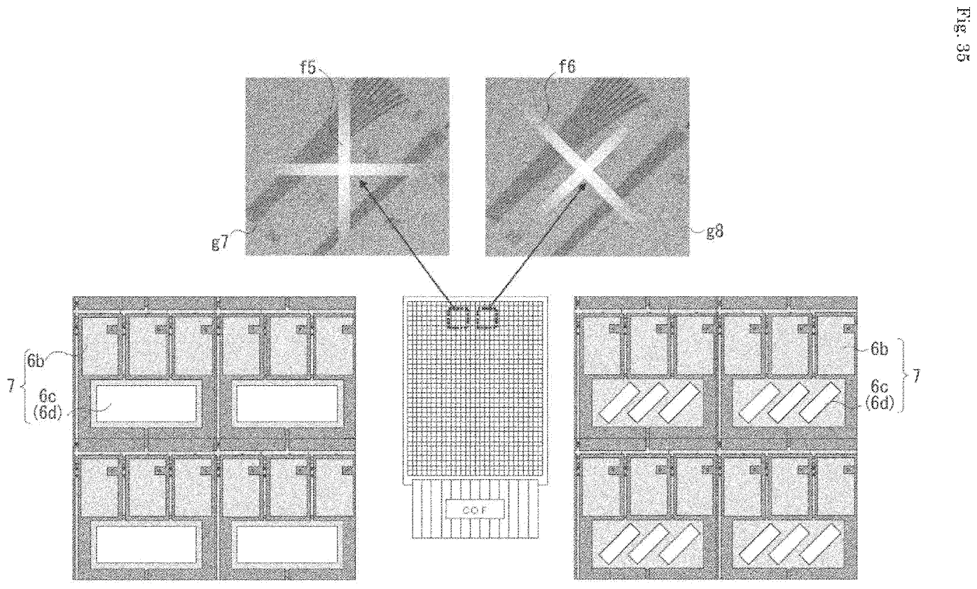

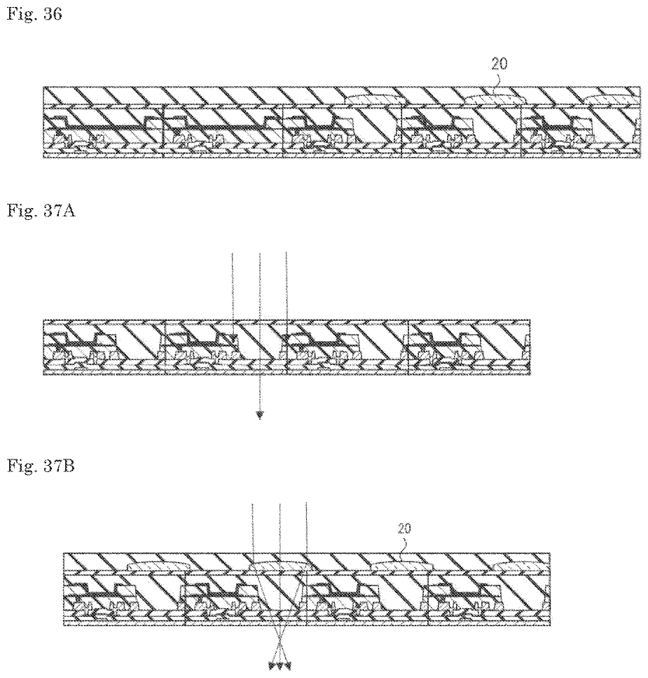

Hence, it is desirable to carry out a measure to concentrate incident light into the transmissive window 6d as much as possible in the first pixel region 6. As a specific measure, a microlens may be provided on the light entry side of the first pixel region 6 so as to concentrate incident light into the transmissive window 6d. FIG. 36 is a cross-sectional view illustrating an example in which a microlens (optical system) 20 is disposed on the light entry side of the first pixel region 6.

The microlens 20 is disposed on the second transparent substrate 41 of the display panel 2 or is formed by working the second transparent substrate 41. The microlens 20 can be formed by performing wet etching or dry etching on resist disposed on a transparent resin material with high transmittance of visible light.

FIG. 37A illustrates arrows indicating the traveling direction of light entering the first pixel region 6 in the absence of the microlens 20. FIG. 37B illustrates arrows indicating the traveling direction of light in the presence of the microlens 20 of FIG. 36. In the absence of the microlens 20, light projected to an opaque member in the first pixel region 6 cannot pass through the transmissive window 6d, thereby reducing the amount of light passing through the transmissive window 6d. In the presence of the microlens 20, parallel rays projected into the microlens 20 are refracted in the focus direction of the microlens 20. Hence, the amount of light passing through the transmissive window 6d can be increased by optimizing the curvature of the microlens 20 to adjust the focal point.

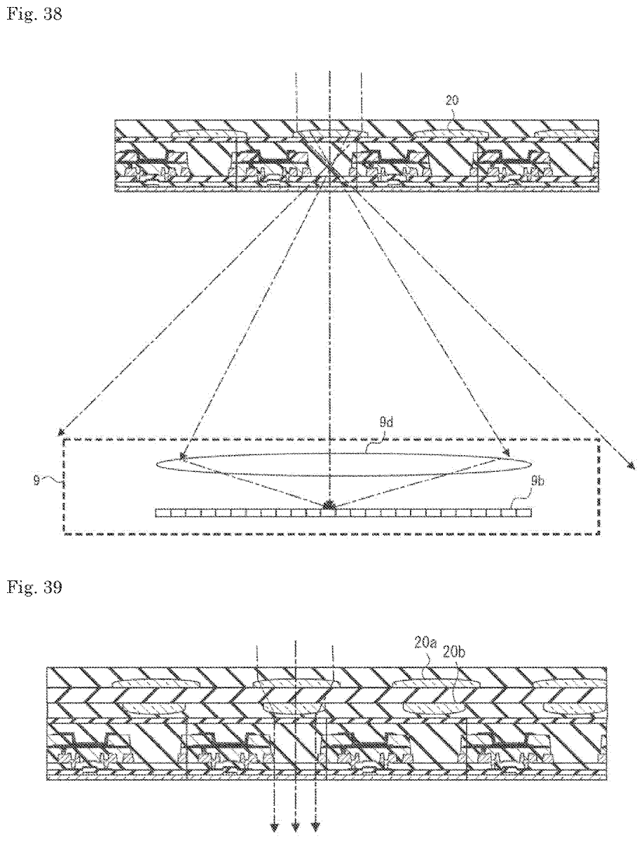

The provision of the single microlens 20 may cause at least part of light refracted through the microlens 20 to diagonally pass through the transmissive window 6d, so that light having passed through the transmissive window 6d may be partially prevented from entering the sensor 5. FIG. 38 illustrates arrows indicating the traveling direction of light refracted through the microlens 20. As illustrated in FIG. 38, the microlens 20 refracts light and thus the refracted light may partially pass through the transmissive window 6d and reach a point deviated from the light-receiving surface of the sensor 5. This may interfere with the effective use of light projected into the microlens 20.

Hence, as illustrated in FIG. 39, a plurality of microlenses 20a and 20b may be disposed to protrude in different directions on the light entry side of the first pixel region 6. In this case, as indicated by arrows in FIG. 39, light refracted through the first microlens 20a is transformed into parallel rays with small beam diameters through the second microlens 20b, and then the parallel rays are projected into the transmissive window 6d. The curvature of the second microlens 20b is adjusted according to the size of the transmissive window 6d, so that parallel rays can be projected over the transmissive window 6d and light can be received by the sensor 5 while hardly distorting an image.

For example, the two microlenses 20a and 20b in FIG. 39 can be formed by stacking transparent resin layers, treating one of the layers by wet etching, and treating the other by dry etching.

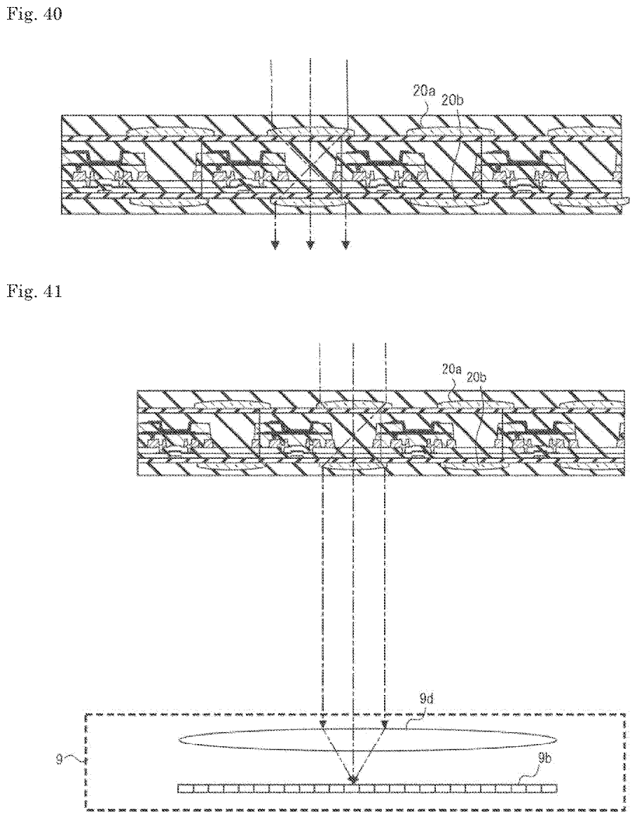

As a modification of FIG. 39 in which the microlenses 20 are disposed along the traveling direction of light, as illustrated in FIG. 40, the microlens (first optical system) 20a may be disposed on the light entry side of the first pixel region 6, and the other microlens (second optical system) 20b may be disposed on the light emission side of the first pixel region 6. The microlens 20a on the light entry side and the microlens 20b on the light emission side protrude in opposite directions. Light projected into the first microlens 20a is refracted and is passed through the transmissive window 6d, and then the light is transformed into parallel rays through the second microlens 20b. The parallel rays are then projected into the sensor 5.

For example, in the image display device 1 of FIG. 40, the second microlens 20b is formed by treating a first transparent resin layer by wet etching or dry etching, and the first microlens 20a is formed by treating a second transparent resin layer by wet etching or dry etching after the layers are formed.

FIG. 41 illustrates arrows indicating the traveling direction of light passing through the two microlenses 20a and 20b of FIG. 40. Light refracted through the first microlens 20a is passed through the transmissive window 6d and is transformed into parallel rays through the second microlens 20b. The parallel rays are then projected into the sensor 5. Thus, unlike in the provision of the single microlens 20 in FIG. 38, light incident on the microlens 20 can be projected into the sensor 5 without being leaked, so that the sensor 5 can have higher sensitivity to received light.

As described above, in the present embodiment, the nonluminous region 6c is provided in the first pixel region 6 located directly above the sensor 5 disposed on the backside of the display panel 2, and the transmissive window 6d in a predetermined shape is provided in the nonluminous region 6c. With this configuration, light incident on the first pixel region 6 passes through the transmissive window 6d and enters the sensor 5. The passage of light through the transmissive window 6d generates the diffracted light f. The transmissive window 6d in a predetermined shape allows the direction of generation of the diffracted light f to be estimated in advance, thereby removing the influence of the diffracted light f from the received signal of the sensor 5. For example, if the sensor 5 is the image sensor module 9, the direction of generation of the diffracted light f is estimated in advance, so that the diffracted light f in image data captured by the image sensor module 9 can be removed by image processing.

Since the shape of the transmissive window 6d of the nonluminous region 6c is determined by the ends of the anode electrode 12a or the ends of the wiring layer, the transmissive window 6d in a desired shape and size can be formed with relative ease. Moreover, since the plurality of transmissive windows 6d in different shapes can be formed in the nonluminous regions 6c of the first pixel regions 6, the influence of the diffracted light f can be canceled by synthesizing the diffracted light f generated by the transmissive windows 6d in different shapes.

The microlens 20 is disposed on the light entry side of the first pixel region 6, so that light projected into the first pixel region 6 is refracted through the microlens 20 and is passed through the transmissive window 6d of the nonluminous region 6c. This can increase the amount of light passing through the transmissive window 6d. Furthermore, the plurality of microlenses 20 are provided along the incident direction of light, so that light having passed through the transmissive window 6d can be guided to the light-receiving surface of the sensor 5 and the amount of light received by the sensor 5 can be increased. Thus, the sensor 5 can have higher sensitivity to received light.

### Second Embodiment

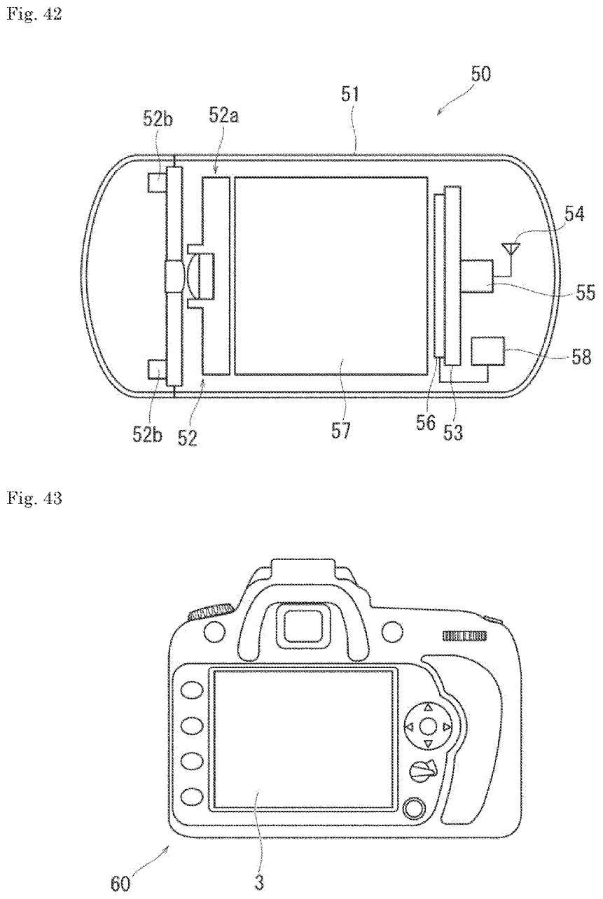

Various devices may be used as specific candidates of the electronic device 50 having the configuration described in the first embodiment. For example, FIG. 42 is a plan view of the electronic device 50 applied to a capsule endoscope according to the first embodiment. For example, the capsule endoscope 50 in FIG. 42 includes, in a cabinet 51 with both end faces hemispherical in shape and a central portion cylindrical in shape, a camera (subminiature camera) 52 for capturing an image in a body cavity, a memory 53 for recording image data acquired by the camera 52, and a radio transmitter 55 for transmitting the recorded image data to the outside via an antenna 54 after the capsule endoscope 50 is discharged out of the body of a subject.

In the cabinet 51, a CPU (Central Processing Unit) 56 and a coil (magnetic force/current converting coil) 57 are further provided. The CPU 56 controls imaging by the camera 52 and an operation for storing data in the memory 53 and controls data transmission from the memory 53 to a data receiver (not illustrated) outside the cabinet 51 by means of the radio transmitter 55. The coil 57 supplies power to the camera 52, the memory 53, the radio transmitter 55, the antenna 54, and light sources 52b, which will be described later.

The cabinet 51 further includes a magnetic (reed) switch 58 for detecting the setting of the capsule endoscope 50 into the data receiver. The CPU 56 supplies power from the coil 57 to the radio transmitter 55 when the reed switch 58 detects the setting into the data receiver and data transmission is enabled.

The camera 52 includes, for example, an image sensor 52a including an objective optical system for capturing an image in a body cavity, and a plurality of light sources 52b for illuminating the body cavity. Specifically, the camera 52 includes, for example, a CMOS (Complementary Metal Oxide Semiconductor) sensor including an LED (Light Emitting Diode) or a CCD (Charge Coupled Device) as the light sources 52b.

A display part 3 in the electronic device 50 according to the first embodiment is a concept including emitters such as the light sources 52b in FIG. 42. For example, the capsule endoscope 50 of FIG. 42 includes the two light sources 52b. The light sources 52b can be configured as a display panel having a plurality of light source units or an LED module having a plurality of LEDs. In this case, the imaging unit of the camera 52 is disposed below the display panel or the LED module so as to reduce constraints to the layout of the camera 52, thereby downsizing the capsule endoscope 50.

FIG. 43 is a rear view of the electronic device 50 applied to a digital single-lens reflex camera 60 according to the first embodiment. The digital single-lens reflex camera 60 and a compact camera are provided with the display part 3 for displaying a preview screen on the back of the camera, that is, on the opposite side of the camera from a lens. Camera modules 4 and 5 may be disposed on the opposite side of the camera from the display surface of the display part 3 so as to display a face image of a photographer on the display surface of the display part 3. In the electronic device 50 according to the first embodiment, the camera modules 4 and 5 can be disposed in a region overlapping the display part 3. This can eliminate the need for providing the camera modules 4 and 5 at the bezel of the display part 3, thereby maximizing the size of the display part 3.

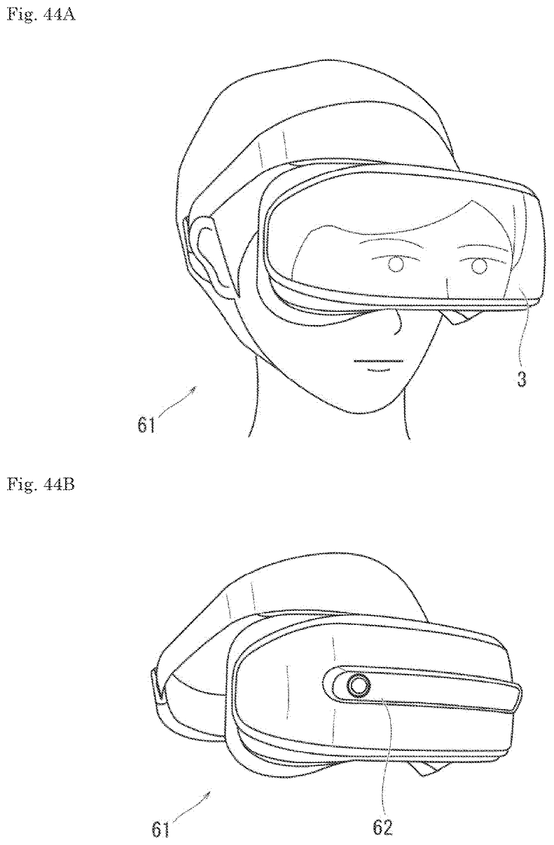

FIG. 44A is a plan view illustrating an example in which the electronic device 50 according to the first embodiment is applied to a head-mounted display (hereinafter referred to as an HMD) 61. The HMD 61 in FIG. 44A is used for, for example, VR (Virtual Reality), AR (Augmented Reality), MR (Mixed Reality), or SR(Substitutional Reality). As illustrated in FIG. 44B, the existing HMD has a camera 62 on the outer surface. A person wearing the HMD can visually recognize an image of a surrounding area but unfortunately, persons around the wearer of the HMD cannot recognize the eyes and facial expressions of the wearer.

For this reason, in FIG. 44A, the display surface of the display part 3 is provided on the outer surface of the HMD 61 and the camera modules 4 and 5 are provided on the opposite side of the HMD 61 from the display surface of the display part 3. Thus, the facial expressions of the wearer imaged by the camera modules 4 and 5 can be displayed on the display surface of the display part 3, allowing persons around the wearer to recognize the facial expressions and eye movements of the wearer in real time.

In the case of FIG. 44A, the camera modules 4 and 5 are provided on the backside of the display part 3. This eliminates constraints to the location of the camera modules 4 and 5, thereby increasing flexibility in the design of the HMD 61. Furthermore, the camera can be disposed at the optimum position, thereby preventing problems such as a deviation of a wearer's line of vision on the display surface.

As described above, in the second embodiment, the electronic device 50 according to the first embodiment can be used for a variety of uses, thereby improving the usefulness.

The present technique can also take on the following configurations.
(1) An image display device including a plurality of pixels that are two-dimensionally arranged,
wherein the plurality of pixels include at least some pixels, each having:
a first self-emitting device;
a first luminous region illuminated by the first self-emitting device; and
a nonluminous region having a transmissive window in a predetermined shape that allows the passage of visible light.
(2) The image display device according to (1), wherein the plurality of pixels include at least two pixels including the nonluminous regions with the transmissive windows in different shapes.
(3) The image display device according to (1) or (2), wherein in plan view from the display surface side of the image display device, the nonluminous region is disposed at a position overlapping a light receiver for receiving light passing through the image display device.
(4) The image display device according to any one of (1) to (3), wherein a pixel circuit connected to the first self-emitting device is disposed in the first luminous region.
(5) The image display device according to any one of (1) to (4), wherein the nonluminous region has the plurality of transmissive windows spaced in one of the pixels.
(6) The image display device according to any one of (1) to (4), wherein the transmissive window is disposed over at least two of the pixels.
(7) The image display device according to (6), wherein the transmissive window disposed over the at least two of the pixels varies in shape and type.
(8) The image display device according to any one of (1) to (7), further including an optical member that is disposed on the light entry side of the transmissive window and refracts incident light so as to guide the light into the transmissive window.
(9) The image display device according to (8), wherein the optical member includes:
a first optical system that refracts incident light in the direction of an optical axis; and
a second optical system that collimates the light refracted by the first optical system,
wherein the transmissive window allows the passage of the light collimated by the second optical system.
(10) The image display device according to any one of (1) to (7), further including:
a first optical member that is disposed on the light entry side of the transmissive window and refracts incident light so as to guide the light into the transmissive window; and
a second optical member that is disposed on the light emission side of the transmissive window and collimates light from the transmissive window so as to guide the light into the light receiver.
(11) The image display device according to any one of (1) to (10), further including:
first pixel regions including some of the plurality of pixels; and second pixel regions including at least some of the plurality of pixels other than the pixels in the first pixel regions,
wherein the pixel in the first pixel region includes the first self-emitting device, the first luminous region, and the nonluminous region, and
the pixel in the second pixel region includes:
a second self-emitting device; and
a second luminous region that is illuminated by the second self-emitting device and has a larger area than the first luminous region.
(12) The image display device according to (11), wherein the first pixel regions are spaced at a plurality of points in a pixel display region.
(13) The image display device according to (11) or (12), wherein in the first pixel regions, at least two of the plurality of pixels are provided with the transmissive windows in different shapes such that diffracted light generated by light having passed through the transmissive windows has different shapes.
(14) The image display device according to any one of (1) to (13), wherein the first self-emitting device includes:
a lower electrode layer;
a display layer disposed on the lower electrode layer;
an upper electrode layer disposed on the display layer; and
a wiring layer that is disposed under the lower electrode layer and is electrically connected to the lower electrode layer via a contact extending from the lower electrode layer in a stacking direction, and
the shape of the transmissive window in plan view from the display surface side of the plurality of pixels is determined by the ends of the lower electrode layer.
(15) The image display device according to any one of (1) to (13), wherein the first self-emitting device includes:
a lower electrode layer;
a display layer disposed on the lower electrode layer;
an upper electrode layer disposed on the display layer; and
a wiring layer that is disposed under the lower electrode layer and is electrically connected to the lower electrode layer via a contact extending from the lower electrode layer in a stacking direction, and
the shape of the transmissive window in plan view from the display surface side of the plurality of pixels is determined by the ends of the wiring layer.
(16) The image display device according to (15), wherein the wiring layer includes a plurality of stacked metallic layers, and
the shape of the transmissive window in plan view from the display surface side of the plurality of pixels is determined by the ends of at least one of the plurality of metallic layers.
(17) The image display device according to (16), wherein the metallic layer is an electrode of a capacitor in the pixel circuit, the metallic layer determining the shape of the transmissive window in plan view from the display surface side of the plurality of pixels.
(18) The image display device according to any one of (14) to (18), wherein the first luminous region is covered with the lower electrode layer except for the region of the transmissive window.
(19) An electronic device including: an image display device including a plurality of pixels that are two-dimensionally arranged, and
a light receiver that receives light passing through the image display device, wherein the image display device has first pixel regions including some of the plurality of pixels,
the pixels in the first pixel regions each include:
a first self-emitting device;
a first luminous region illuminated by the first self-emitting device; and
a nonluminous region having a transmissive window in a predetermined shape that allows the passage of visible light, and
in plan view from the display surface side of the image display device, at least some of the first pixel regions are disposed so as to overlap the light receiver.
(20) The electronic device according to (19), wherein the light receiver receives light through the nonluminous region.
(21) The electronic device according to (19) or (20), wherein the light receiver includes at least one of an imaging sensor that performs photoelectric conversion on incident light passing through the nonluminous region, a distance measuring sensor that receives incident light passing through the nonluminous region and measures a distance, and a temperature sensor that measures a temperature on the basis of incident light passing through the nonluminous region.

Aspects of the present disclosure are not limited to the aforementioned individual embodiments and include various modifications that those skilled in the art can achieve, and effects of the present disclosure are also not limited to the details described above. In other words, various additions, modifications, and partial deletion can be made without departing from the conceptual idea and the gist of the present disclosure that can be derived from the details defined in the claims and the equivalents thereof.

### REFERENCE SIGNS LIST

1 Image display device
2 Display panel
2a Display layer
5 Sensor
6 First pixel region
6a First self-emitting device
6b First luminous region
6c Nonluminous region
6d Transmissive window
7 Pixel
8 Second pixel region
8a Second self-emitting device
8b Second luminous region
9 Image sensor module
9a Support substrate
9b Image sensor
9c Cutoff filter
9d Lens unit
9e Coil
9f Magnet
9g Spring
10 Subject
11 Specific pixel
12 Pixel circuit
12a Anode electrode
31 First transparent substrate
32 First insulating layer
33 First wiring layer
34 Second insulating layer
35 Second wiring layer
36 Third insulating layer
36a Trench
37 Fourth insulating layer
38 Anode electrode layer
39 Cathode electrode layer
40 Fifth insulating layer
41 Second transparent substrate
42 Semiconductor layer
43 Capacitor
44 Metallic layer
45 Third metallic layer

1. An image display device comprising a plurality of pixels that are two-dimensionally arranged,
wherein the plurality of pixels include at least some pixels, each having:
a first self-emitting device;
a first luminous region illuminated by the first self-emitting device; and
a nonluminous region having a transmissive window in a predetermined shape that allows passage of visible light.

2. The image display device according to claim 1, wherein the plurality of pixels include at least two pixels including the nonluminous regions with the transmissive windows in different shapes.

3. The image display device according to claim 1, wherein in plan view from a display surface side of the image display device, the nonluminous region is disposed at a position overlapping a light receiver for receiving light passing through the image display device.

4. The image display device according to claim 1, wherein a pixel circuit connected to the first self-emitting device is disposed in the first luminous region.

5. The image display device according to claim 1, wherein the nonluminous region has the plurality of transmissive windows spaced in one of the pixels.

6. The image display device according to claim 1, wherein the transmissive window is disposed over at least two of the pixels.

7. The image display device according to claim 6, wherein the transmissive window disposed over the at least two of the pixels varies in shape and type.

8. The image display device according to claim 1, further comprising an optical member that is disposed on a light entry side of the transmissive window and refracts incident light so as to guide the light into the transmissive window.

9. The image display device according to claim 8, wherein the optical member comprises:
a first optical system that refracts incident light in a direction of an optical axis; and
a second optical system that collimates the light refracted by the first optical system,
wherein the transmissive window allows passage of the light collimated by the second optical system.

10. The image display device according to claim 1, further comprising:
a first optical member that is disposed on a light entry side of the transmissive window and refracts incident light so as to guide the light into the transmissive window; and
a second optical member that is disposed on a light emission side of the transmissive window and collimates light from the transmissive window so as to guide the light into a light receiver.

11. The image display device according to claim 1, further comprising:
first pixel regions including some of the plurality of pixels; and
second pixel regions including at least some of the plurality of pixels other than the pixels in the first pixel regions,
wherein the pixel in the first pixel region includes the first self-emitting device, the first luminous region, and the nonluminous region, and
the pixel in the second pixel region includes:
a second self-emitting device; and
a second luminous region that is illuminated by the second self-emitting device and has a larger area than the first luminous region.

12. The image display device according to claim 11, wherein the first pixel regions are spaced at a plurality of points in a pixel display region.

13. The image display device according to claim 11, wherein in the first pixel regions, at least two of the plurality of pixels are provided with the transmissive windows in different shapes such that diffracted light generated by light having passed through the transmissive windows has different shapes.

14. The image display device according to claim 1, wherein the first self-emitting device includes:
a lower electrode layer;
a display layer disposed on the lower electrode layer;
an upper electrode layer disposed on the display layer; and
a wiring layer that is disposed under the lower electrode layer and is electrically connected to the lower electrode layer via a contact extending from the lower electrode layer in a stacking direction, and
the shape of the transmissive window in plan view from a display surface side of the plurality of pixels is determined by ends of the lower electrode layer.

15. The image display device according to claim 1, wherein the first self-emitting device includes:
a lower electrode layer;
a display layer disposed on the lower electrode layer;
an upper electrode layer disposed on the display layer; and
a wiring layer that is disposed under the lower electrode layer and is electrically connected to the lower electrode layer via a contact extending from the lower electrode layer in a stacking direction, and
the shape of the transmissive window in plan view from a display surface side of the plurality of pixels is determined by ends of the wiring layer.

16. The image display device according to claim 15, wherein the wiring layer includes a plurality of stacked metallic layers, and
the shape of the transmissive window in plan view from the display surface side of the plurality of pixels is determined by ends of at least one of the plurality of metallic layers.

17. The image display device according to claim 16, wherein the metallic layer is an electrode of a capacitor in the pixel circuit, the metallic layer determining the shape of the transmissive window in plan view from the display surface side of the plurality of pixels.

18. The image display device according to claim 14, wherein the first luminous region is covered with the lower electrode layer except for a region of the transmissive window.

19. An electronic device comprising: an image display device including a plurality of pixels that are two-dimensionally arranged, and
a light receiver that receives light passing through the image display device, wherein the image display device has first pixel regions including some of the plurality of pixels,
the pixels in the first pixel regions each include:
a first self-emitting device;
a first luminous region illuminated by the first self-emitting device; and
a nonluminous region having a transmissive window in a predetermined shape that allows the passage of visible light, and
in plan view from a display surface side of the image display device, at least some of the first pixel regions are disposed so as to overlap the light receiver.

20. The electronic device according to claim 19, wherein the light receiver receives light through the nonluminous region.

21. The electronic device according to claim 19, wherein the light receiver includes at least one of an imaging sensor that performs photoelectric conversion on incident light passing through the nonluminous region, a distance measuring sensor that receives incident light passing through the nonluminous region and measures a distance, and a temperature sensor that measures a temperature on a basis of incident light passing through the nonluminous region.
